(19) United States
(12) Patent Application Publication
(10) Pub. No.: US 2026/0196173 A1
(43) Pub. Date: Jul. 9, 2026

(54) DISPLAY PANEL, DISPLAY APPARATUS INCLUDING THE SAME, AND METHOD OF DRIVING DISPLAY APPARATUS

(71) Applicant: LG Display Co., Ltd., Seoul (KR)

(72) Inventors: Byungsam MIN, Goyang-si (KR); Wonho LEE, Paju-si (KR); Inyeong KONG, Seoul (KR)

(73) Assignee: LG Display Co., Ltd., Seoul (KR)

(21) Appl. No.: 19/376,679

(22) Filed: Oct. 31, 2025

(30) Foreign Application Priority Data
Dec. 18, 2024 (KR) 10-2024-0190224

(51) Int. Cl. G09G 3/3233; G09G 3/3266

(52) U.S. Cl. CPC G09G 3/3233; G09G 3/3266; G09G 2300/0819; G09G 2300/0852; G09G 2310/0286; G09G 2310/0297; G09G 2310/06; G09G 2310/08; G09G 2320/0233; G09G 2330/023

(57) ABSTRACT

A display panel, a display apparatus including the same and a method of driving the display apparatus are discussed. The display panel can include a first pixel including a plurality of sub-pixels, a second pixel disposed at a location adjacent to the first pixel and including a plurality of sub-pixels, a first reference voltage line that supplies a reference voltage to the first pixel, a second reference voltage line that supplies a reference voltage to the second pixel, and a switch unit that is connected to the first reference voltage line and the second reference voltage line.

### CROSS-REFERENCE TO RELATED APPLICATION

The present application claims priority to Korean Patent Application No. 10-2024-0190224, filed in the Republic of Korea on Dec. 18, 2024, the entire contents of which is incorporated by reference.

### BACKGROUND

### Field

The present specification relates to a display apparatus, and more specifically, to a display panel that reflects the characteristics of an adjacent pixel in a compensation value and separately drives a plurality of reference voltage lines, a display apparatus including the same, and a method of driving a display apparatus.

### Discussion of the Related Art

Display apparatuses used in computer monitors, TVs, mobile phones, etc. include organic light-emitting diode (OLED) displays that emit light by themself, liquid crystal display (LCD) apparatuses that require a separate light source, etc.

Among various display apparatuses, the OLED display apparatus includes a display panel including a plurality of pixels and a driving unit that drives the display panel. The driving unit includes a gate driver that supplies a gate signal to the display panel and a data driver that supplies a data voltage. When signals, such as the gate signal, the data voltage, etc., are supplied to a sub-pixel included in each pixel of the OLED display apparatus, a selected sub-pixel emits light to display an image.

### SUMMARY OF THE DISCLOSURE

In conventional display apparatuses, when being operated by a single rate driving (SRD) or double rate driving (DRD) method, there can be a limitation that ratios of driving and sensing are different and a source drive integrated circuit (IC) cannot be shared due to the compensation of a driving transistor and an increase in visibility of a light-emitting element.

In addition, in the conventional display apparatuses, when reference voltage lines have a bundle structure during the SRD or DRD driving, the compensation time increases, and degradation of image quality can occur due to the defect of the reference voltage line.

In addition, in the conventional display apparatuses, there is a possibility that a bezel of a data pad part can increase due to a data link during the SRD or DRD driving.

Accordingly, the inventors of the present disclosure have invented a display panel that can share a source drive IC by arranging a switch in a non-pad part to switch a sensing channel in order to make a ratio of driving and sensing lines the same during the DRD driving and improve image quality by separately driving reference voltage lines.

In addition, the present disclosure provides a display panel on which at least one switch is disposed to selectively sense characteristics of one of first and second pixels, and a display apparatus including the same.

In addition, the present disclosure provides a display panel on which at least one switch that switches a path along which a reference voltage is transmitted to one of a first reference voltage line and a second reference voltage line is disposed to separately drive the first reference voltage line and the second reference voltage line, and a display apparatus including the same.

In addition, the present disclosure provides a display panel in which an increase in a bezel of a data pad part is prevented by arranging at least one switch in a non-pad part, and a display apparatus including the same.

In addition, the present disclosure provides a display panel including a switch part including a sensing switch for selectively sensing characteristics of one of first and second pixels and a driving switch for separately driving a first reference voltage line and a second reference voltage line, and a display apparatus including the same.

In addition, the present disclosure provides a display panel including a switch that is switched to an OFF state so that characteristics of a first pixel is applied as a compensation value of a second pixel and switched to an ON state so that a reference voltage is transmitted to a first reference voltage line and a second reference voltage line, a display apparatus including the same, and a method of driving a display apparatus.

Objects of the present disclosure are not limited to the above objects, and other objects and advantages of the present disclosure that are not mentioned can be understood by the following description and more clearly understood by embodiments of the present disclosure. In addition, it will be able to be easily seen that the objects and advantages of the present disclosure can be achieved by devices and combinations thereof that are described in the claims.

A display panel according to one embodiment of the present disclosure includes a switch unit including at least one switch that is connected to a first reference voltage line and a second reference voltage line and selectively senses characteristics of one of the first and second pixels.

In addition, the display panel according to one embodiment of the present disclosure includes a switch unit including a sensing switch that selectively senses characteristics of an adjacent pixel and a driving switch that performs switching to separately drive the reference voltage lines.

In addition, the display panel according to one embodiment of the present disclosure includes a sensing switch that maintains an OFF state so that characteristics of the first pixel are applied to a compensation value of the second pixel located at an adjacent location.

In addition, the display panel according to one embodiment of the present disclosure includes a sensing switch that is switched to ON so that a reference voltage is transmitted to the first reference voltage line and the second reference voltage line when the characteristics of the first pixel are defective.

In addition, the display panel according to one embodiment of the present disclosure includes a driving switch that is switched from ON to OFF when the sensing switch is switched from OFF to ON.

In addition, the display panel according to one embodiment of the present disclosure includes a switch unit disposed in a non-display area.

In addition, the display panel according to one embodiment of the present disclosure includes a sensing line that transmits a sensing signal for sensing the characteristics of the first pixel to the sensing switch, and a driving line that transmits a driving signal for separately driving the first reference voltage line and the second reference voltage line to the driving switch.

In addition, a display apparatus according to one embodiment of the present disclosure includes a display panel including a switch that selectively senses characteristics of one of a first pixel and a second pixel and separately drives a first reference voltage line and a second reference voltage line.

In addition, a method of driving a display apparatus according to one embodiment of the present disclosure includes a process of performing switching to selectively sense characteristics of a sub-pixel of one of a first pixel and a second pixel of a display panel and separately driving a first reference voltage line and a second reference voltage line so that a reference voltage is transmitted to one of the first reference voltage line and the second reference voltage line.

According to the embodiments of the present disclosure, it is possible to share the source drive IC by selectively sensing the characteristics of one of the first pixel and the second pixel and providing at least one switch for separately driving the reference voltage lines.

In addition, according to the embodiments of the present disclosure, it is possible to share the source drive IC with a reduction in the number of sensing channels and reduce the cost by sensing the characteristics of the first sub-pixel of the first pixel through the sensing switch and reflecting the sensed characteristics in the compensation value of the first sub-pixel of the second pixel.

In addition, according to the embodiments of the present disclosure, it is possible to shorten the compensation time and improve image quality by designing two reference voltage lines to be a single bundle structure through the driving switch and switching the path along which the reference voltage is transmitted to one of the first reference voltage line disposed in the first pixel and the second reference voltage line disposed in the second pixel.

In addition, according to the embodiments of the present disclosure, it is possible to prevent an increase in the bezel width of the data pad part by arranging the switching part including at least one sensing switch and at least one driving switch in the non-display area (e.g., the bezel area or the edge area).

In addition, according to the embodiments of the present disclosure, it is possible to reduce power consumption by sensing the characteristics of the first sub-pixel of the first pixel and reflecting the compensation value of the first sub-pixel of the second pixel adjacent to the first pixel.

Effects of the present disclosure are not limited to the above-described effects, and other effects that are not described will be able to be clearly understood by those skilled in the art based on the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic view of a display apparatus according to one or more embodiments of the present disclosure.

FIG. 2 is a circuit diagram of a sub-pixel of the display apparatus according to one embodiment of the present disclosure.

FIG. 3 shows a compensation circuit of a display apparatus according to embodiments of the present disclosure.

FIG. 4 is a first example view showing a driving method of a display panel according to the embodiments of the present disclosure.

FIG. 5 is a second example view showing a driving method of a display panel according to one embodiment of the present disclosure.

FIG. 6 is a third example view showing a driving method of a display panel according to one embodiment of the present disclosure.

FIG. 7 is a fourth example view showing a plurality of switch elements M1 and M2 added to the driving method of the display panel of FIG. 5.

FIG. 8 is a fifth example view showing a driving method of a display panel according to one embodiment of the present disclosure.

FIG. 9 is a circuit diagram of a first sub-pixel and a second sub-pixel for compensating for a second sub-pixel through characteristics of the first sub-pixel according to one embodiment of the present disclosure.

FIG. 10 is a timing diagram for describing sensing driving of the pixel of FIG. 9.

FIG. 11 is a circuit diagram showing additional sensing for the second sub-pixel after compensating for the second sub-pixel through the characteristics of the first sub-pixel according to one embodiment of the present disclosure.

FIG. 12 is a timing diagram for explaining the sensing driving of the pixel of FIG. 11.

FIG. 13 is a circuit diagram for separately driving a first reference voltage line Ref.1(A) and a first reference voltage line Ref.1(B) when the characteristics of the first sub-pixel is defective according to one embodiment of the present disclosure.

FIG. 14 is a timing diagram for describing the sensing driving of the pixel of FIG. 13.

FIG. 15 is a flowchart showing a process of compensating for mobility and image quality of the sub-pixel by turning on a sensing switch after turning on power of the display panel according to one embodiment of the present disclosure.

FIG. 16 is a flowchart showing a process of compensating for the mobility and image quality in real time by turning on the sensing switch while the display panel is being driven according to one embodiment of the present disclosure.

FIG. 17 is a flowchart showing a process of compensating for a threshold voltage and image quality of the sub-pixel after turning off the power of the display panel according to one embodiment of the present disclosure.

FIG. 18 is a flowchart showing a process of compensating for the mobility and image quality of the sub-pixel by turning on the sensing switch of the display panel and turning off a driving switch of the display panel according to one embodiment of the present disclosure.

FIG. 19 is a flowchart showing a process of compensating for the mobility and image quality in real time by turning on the sensing switch while the display panel is being driven according to one embodiment of the present disclosure.

FIG. 20 is a flowchart showing a process of compensating for a threshold voltage and image quality of the sub-pixel after turning off the power of the display panel according to one embodiment of the present disclosure.

### DETAILED DESCRIPTION OF THE EMBODIMENTS

Advantages and features of the present disclosure and methods for achieving them will become clear by referencing embodiments described below in detail in conjunction with the accompanying drawings. However, the present disclosure is not limited to the embodiments disclosed below but can be implemented in various different forms, these embodiments are merely provided to make the features of the present disclosure complete and fully inform those skilled in the art to which the present disclosure pertains of the scope of the present disclosure.

In the present disclosure, in adding reference numerals to components in each drawing, it should be noted that the same components have the same reference numerals as much as possible even when they are shown in different drawings.

Since shapes, sizes, ratios, angles, numbers, etc. disclosed in the drawings for describing the embodiments of the present disclosure are illustrative, the present disclosure is not limited to the shown items. The same reference number denotes the same components throughout the disclosure. In addition, in describing the present disclosure, when it is determined that the detailed description of a related known technology can unnecessarily obscure the gist of the present disclosure, the detailed description thereof will be omitted. When “comprises,” “has,” “consists of,” and the like described in the present disclosure are used, other parts can be added unless “only” is used. When a component is expressed in a singular form, it includes a case in which the component is provided as a plurality of components unless specifically stated otherwise.

In construing a component, the component is construed as including a margin of error even when there is no separate explicit description.

When a positional relationship is described, for example, when the positional relationship between two parts is described using terms such as “on,” “above,” “under,” “next to,” etc., one or more other parts can be positioned between the two parts unless “immediately” or “directly” is used.

When a temporal relationship is described, for example, when the temporal relationship is described using term such as “after,” “subsequently,” “then,” “before,” etc., it can include a non-consecutive case unless the term “immediately” or “directly” is used.

In the description of the signal flow relationship, for example, in the case of “a signal is transmitted from node A to node B,” a case in which the signal is transmitted from node A to node B via another node can be included unless “immediately” or “directly” is used.

Although terms such as first and second are used to describe various components, these components are not limited by these terms. The terms are only used to distinguish one component from another. Therefore, a first component described below can be a second component within the technical spirit of the present disclosure. Further, the term “can” fully encompasses all the meanings and coverages of the term “may” and vice versa.

Features of various embodiments of the present disclosure can be coupled or combined partially or entirely, various technological interworking and driving are made possible, and the embodiments can be implemented independently of each other or implemented together in an associated relationship.

In describing the embodiments of the present disclosure, the descriptions of components that are the same as or correspond to those of the previous or other embodiments will be omitted or may be briefly provided.

Hereinafter, a display panel and a display apparatus including the same according to embodiments of the present disclosure will be described with reference to the drawings. All the components of each display panel and each display apparatus/device according to all embodiments of the present disclosure are operatively coupled and configured.

A transistor used in the display apparatus of the present disclosure can be implemented as one or more of an n-channel transistor (NMOS) and a p-channel transistor (PMOS). The transistor can be implemented as an oxide semiconductor transistor having an oxide semiconductor as an active layer or a low temperature poly-silicon (LTPS) transistor having LTPS as an active layer. The transistor can include at least a gate electrode, a source electrode, and a drain electrode. The transistor can be implemented as a thin film transistor (TFT) on the display panel. In the transistor, carriers flow from the source electrode to the drain electrode. In the case of the n-channel transistor (NMOS), since carriers are electrons, a source voltage has a voltage lower than a drain voltage so that electrons can flow from the source electrode to the drain electrode. In the n-channel transistor (NMOS), a current flows in a direction from the drain electrode to the source electrode, and the source electrode can be an output terminal. In the case of the p-channel transistor (PMOS), since the carriers are holes, the source voltage is higher than the drain voltage so that the holes can flow from the source electrode to the drain electrode. In a p-channel transistor (PMOS), since the holes flow from the source electrode to the drain electrode, a current flows from the source to the drain, and the drain electrode can be an output terminal. Accordingly, it should be noted that the source and drain of the transistor are not fixed because the source and the drain can be changed according to an applied voltage. The source may be the drain, and the drain may be the source. Also, the source in any one aspect of the present disclosure may be the drain in another aspect of the present disclosure, and the drain in any one aspect of the present disclosure may be the source in another aspect of the present disclosure.

In the present disclosure, it is assumed that the transistor is an n-channel transistor (NMOS), but the embodiments of the present disclosure are not limited thereto, and a p-channel transistor can be used, and a circuit configuration can be changed accordingly.

A gate signal of the transistor used as switching elements swings between a gate on voltage and a gate off voltage. The gate on voltage is set as a voltage higher than a threshold voltage (Vth) of the transistor, and the gate off voltage is set as a voltage lower than the threshold voltage (Vth) of the transistor. The transistor is turned on in response to the gate on voltage, while the transistor is turned off in response to the gate off voltage. In the case of the n-channel transistor (NMOS), the gate on voltage can be a gate high voltage (VGH), and the gate off voltage can be a gate low voltage (VGL). In the case of the p-channel transistor (PMOS), the gate on voltage can be the gate low voltage (VGL), and the gate off voltage can be the gate high voltage (VGH).

Hereinafter, various embodiments of the present disclosure will be described in detail with reference to the accompanying drawings.

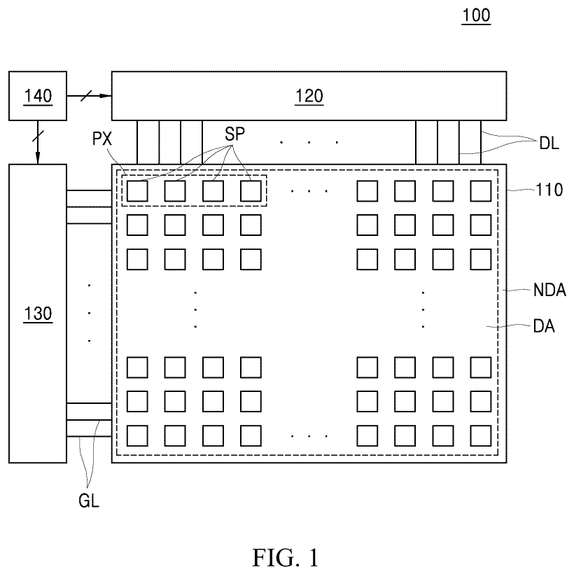

FIG. 1 is a schematic view of a display apparatus according to one or more embodiments of the present disclosure.

Referring to FIG. 1, a display apparatus 100 according to one embodiment of the present disclosure can include a display panel 110, a data driver 120, a gate driver 130, and a timing controller 140, and other circuit components.

The configuration of the display panel 110 according to one embodiment is shown in FIG. 1, and components of the display panel 110 are not limited to the embodiment shown in FIG. 1, and some components can be added, changed, or omitted as needed.

According to one embodiment of the present disclosure, the display panel 110 is a panel for displaying an image. The display panel 110 can include various circuits, lines, and light-emitting elements that are disposed on a substrate. The display panel 110 can include a plurality of pixels PX that are divided by a plurality of data lines DL and a plurality of gate lines GL that intersect each other and connected to the plurality of data lines DL and the plurality of gate lines GL.

The display panel 110 can include a display area DA defined by the plurality of pixels PX and a non-display area NDA in which various signal lines, pads, etc. are formed.

The non-display area NDA may be an area outside of the display area DA, and also be referred to as an edge area or a bezel area. All or a portion of the non-display area NDA may be an area visible from the front surface of the display apparatus 100, or an area that is bent and invisible from the front surface of the display apparatus 100 or an area that is covered by a case or housing (not shown) of the display apparatus 100.

The display panel 110 can be implemented as the display panel 110 used in various display apparatuses such as a liquid crystal display apparatus (LCD), a plasma display device (PDP), a field emission display device (FED), an organic light-emitting diode display apparatus, an electrophoretic display apparatus, etc.

Hereinafter, the display panel 110 will be described as a panel used in an organic light-emitting diode display apparatus, but is not limited thereto.

According to one embodiment of the present disclosure, the timing controller 140 can receive timing signals, such as a vertical synchronization signal, a horizontal synchronization signal, a data enable signal, a dot clock, etc., through a reception circuit such as a low voltage differential signaling (LVDS) or transition minimized differential signaling (TMDS) interface, etc. connected to a host system. In addition, the timing controller 140 can generate timing control signals for controlling the data driver 120 and the gate driver 130 based on the input timing signals.

According to one embodiment of the present disclosure, the data driver 120 can supply a data voltage DATA to a plurality of sub-pixels SP. The data driver 120 can include a plurality of source drive integrated circuits (ICs). The plurality of source drive ICs can receive digital video data and a source timing control signal from the timing controller 140.

The plurality of source drive ICs can convert digital video data into a gamma voltage in response to the source timing control signal to generate the data voltage DATA and supply the data voltage DATA through a data line DL of the display panel 110. The plurality of source drive ICs can be connected to the data line DL of the display panel 110 by a chip on glass (COG) process or a tape automated bonding (TAB) process.

In addition, the source drive ICs can be formed on the display panel 110 or formed on a separate printed circuit board (PCB) substrate and connected to the display panel 110.

According to one embodiment of the present disclosure, the gate driver 130 can supply gate signals to the plurality of sub-pixels SP. The gate driver 130 can include a level shifter and a shift register. The level shifter can shift a level of a clock signal input from the timing controller 140 as a level of a transistor-transistor-logic (TTL) and then supply the clock signal to the shift register. The shift register can be formed in a non-display area NDA of the display panel 110 in a gate in panel (GIP) manner, but is not limited thereto.

In addition, the shift register can be composed of a plurality of stages that shift and output gate signals in response to the clock signal and the driving signal. The plurality of stages included in the shift register can sequentially output the gate signals through a plurality of output terminals.

According to one embodiment of the present disclosure, the gate driver 130 can be connected to the display panel 110 in a TAB manner, connected to a conductive pad such as a bonding pad of the display panel 110 in a COG or chip on panel (COP) manner, or connected to the display panel 110 in a chip on film (COF) manner. Alternatively, the gate driver 130 can be formed in the non-display area NDA of the display panel 110 in a GIP type, without being limited thereto. Alternatively, the gate driver 130 may be disposed in the display area DA of the display panel 110. The gate driver 130 can be disposed on or connected to the substrate. For example, the gate driver 130 can be disposed in the non-display area NDA of the substrate in the case of the GIP type. The gate driver 130 can be connected to the substrate in the case of the COG type, the COF type, etc.

According to one embodiment of the present disclosure, the display panel 110 can include the plurality of sub-pixels SP. The plurality of sub-pixels SP can be sub-pixels SP for emitting different colors. For example, the plurality of sub-pixels SP can be a red sub-pixel, a green sub-pixel, a blue sub-pixel, and a white sub-pixel, respectively, but are not limited thereto. The plurality of sub-pixels SP can constitute a pixel PX. In another exemplary embodiment, each sub-pixel SP may display one color among cyan, magenta and yellow.

For example, a red sub-pixel (R), a green sub-pixel (G), a blue sub-pixel (B), and a white sub-pixel (W) can constitute one pixel PX, and the display panel 110 can include a plurality of pixels PX.

According to one embodiment of the present disclosure, the display panel 110 can include the plurality of sub-pixels SP disposed on the substrate to display an image. For example, the plurality of sub-pixels SP can be disposed in the display area DA. In some cases, at least one sub-pixel SP can be disposed in the non-display area NDA. At least one sub-pixel SP disposed in the non-display area NDA is also referred to as a dummy sub-pixel.

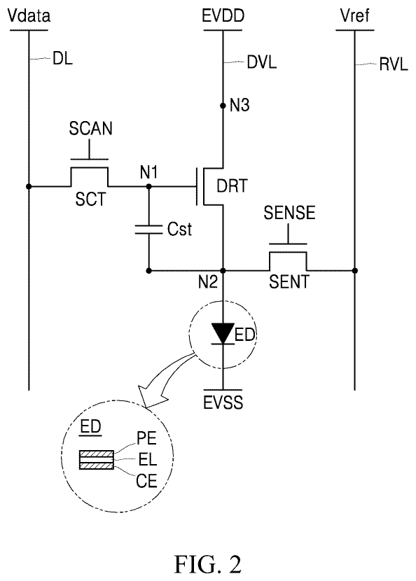

Hereinafter, a more detailed description of the driving unit for driving one sub-pixel SP will be given with reference to FIG. 2 together.

FIG. 2 is a circuit diagram of a sub-pixel of the display apparatus according to one embodiment of the present disclosure. For example, FIG. 2 illustrates a circuit diagram of one sub-pixel SP among the plurality of sub-pixels SP of the display apparatus 100.

Referring to FIG. 2, in the display apparatus 100 according to the embodiments of the present disclosure, each sub-pixel SP can include a light-emitting element ED, a driving transistor DRT for supplying a driving current to the light-emitting element ED for driving the light-emitting element ED, a scan transistor SCT for transmitting the data voltage Vdata to the driving transistor DRT, a storage capacitor Cst for maintaining a voltage for a predetermined period, etc.

According to one embodiment of the present disclosure, the scan transistor SCT can control a voltage state of a first node N1 of the driving transistor DRT in order to control a driving state of the sub-pixel SP. Each sub-pixel SP can further include a sense transistor SENT that can control a voltage state of a second node N2 of the driving transistor DRT in order to control the driving state of the sub-pixel SP.

The sub-pixel SP shown in FIG. 2 has a 3T (transistor) 1C (capacitor) structure because it has three transistors DRT, SCT, and SENT and one capacitor Cst to drive the light-emitting element ED, but is not limited thereto. For example, 4T1C, 5T1C, 3T2C, 4T2C, 5T2C, 6T2C, 7T1C, 7T2C, 8T2C structures, etc. are also possible. And more or less transistors and capacitors could be included.

According to one embodiment of the present disclosure, the light-emitting element ED can include a pixel electrode PE, a common electrode CE, and a light-emitting layer EL located between the pixel electrode PE and the common electrode CE. The pixel electrode PE of the light-emitting element ED can be an anode electrode or a cathode electrode. The common electrode CE can be a cathode electrode or an anode electrode. A base voltage EVSS corresponding to a common voltage can be applied to the common electrode CE of the light-emitting element ED. Here, the base voltage EVSS can be, for example, a ground voltage or a voltage similar to the ground voltage. For example, the light-emitting element ED can be an organic light-emitting diode (OLED), an inorganic-based light-emitting diode (LED), a quantum dot light-emitting element, etc.

For example, the light-emitting layer EL may include one or more of a hole injection layer (HIL), a hole transmitting layer (HTL), an electron transmitting layer (ETL) and an electron injection layer (EIL), but the present disclosure is not limited thereto.

According to one embodiment of the present disclosure, the driving transistor DRT is a transistor for driving the light-emitting element ED and can include the first node N1, the second node N2, a third node N3, etc. The first node N1 of the driving transistor DRT is a node corresponding to a gate node and can be electrically connected to a source or drain node of the scan transistor SCT. The second node N2 of the driving transistor DRT is a source or drain node and can be electrically connected to a source or drain node of the sense transistor SENT and electrically connected to the pixel electrode PE of the light-emitting element ED. The third node N3 of the driving transistor DRT can be a drain or source node and can be electrically connected to a driving voltage line DVL that supplies the driving voltage EVDD. Hereinafter, for convenience of description, an example in which the second node N2 of the driving transistor DRT can be a source node, and the third node N3 can be a drain node will be described, but is not limited thereto. For example, the second node N2 of the driving transistor DRT may be a drain node, and the third node N3 may be a source node.

According to one embodiment of the present disclosure, the scan transistor SCT can be connected between the data line DL and the first node N1 of the driving transistor DRT. The scan transistor SCT can control connection between the first node N1 of the driving transistor DRT and a corresponding data line DL among the plurality of data lines DL in response to the scan signal SCAN supplied from a corresponding scan signal line SCL among a plurality of scan signal lines SCL, which are a type of gate line GL. For example, the scan transistor SCT may be turned on or off in response to the scan signal SCAN.

According to one embodiment of the present disclosure, the drain node or source node of the scan transistor SCT can be electrically connected to a corresponding data line DL. The source node or drain node of the scan transistor SCT can be electrically connected to the first node N1 of the driving transistor DRT. A gate node of the scan transistor SCT can be electrically connected to the scan signal line SCL, which is a type of gate line GL, to receive the scan signal SCAN.

According to one embodiment of the present disclosure, the scan transistor SCT can be turned on by the scan signal SCAN of a turn-on level voltage and can transmit the data voltage Vdata supplied from the corresponding data line DL to the first node N1 of the driving transistor DRT. The scan transistor SCT can be turned on by the scan signal SCAN of the turn-on level voltage and turned off by the scan signal SCAN of the turn-off level voltage. For example, the scan transistor SCT may be turned off by the scan signal SCAN of the turn-off level voltage, and the data voltage Vdata supplied from the corresponding data line DL cannot be supplied to the first node N1 of the driving transistor DRT.

Here, when the scan transistor SCT is an n-type, the turn-on level voltage can be a high-level voltage, and the turn-off level voltage can be a low-level voltage. When the scan transistor SCT is a p-type, the turn-on level voltage can be a low-level voltage, and the turn-off level voltage can be a high-level voltage.

According to one embodiment of the present disclosure, the sense transistor SENT can be connected between the second node N2 of the driving transistor DRT and a reference voltage line RVL. The sense transistor SENT can control connection between the second node N2 of the driving transistor DRT electrically connected to the pixel electrode PE of the light-emitting element ED and a corresponding reference voltage line RVL among the plurality of reference voltage lines RVL in response to the sense signal SENSE supplied from a corresponding sense signal line SENL among a plurality of sense signal lines SENL, which are a type of gate line GL. For example, the sense transistor SENT may be turned on or off in response to the sense signal SENSE.

According to one embodiment of the present disclosure, the drain node or source node of the sense transistor SENT can be electrically connected to the reference voltage line RVL. The source node or drain node of the sense transistor SENT can be electrically connected to the second node N2 of the driving transistor DRT and electrically connected to the pixel electrode PE of the light-emitting element ED. A gate node of the sense transistor SENT can be electrically connected to the sense signal line SENL, which is a type of gate line GL, to receive the sense signal SENSE.

According to one embodiment of the present disclosure, the sense transistor SENT can be turned on to apply a reference voltage V_{ref} supplied from the reference voltage line RVL to the second node N2 of the driving transistor DRT. The sense transistor SENT is turned on by the sense signal SENSE of a turn-on level voltage and turned off by the sense signal SENSE of a turn-off level voltage. For example, the sense transistor SENT may be turned off by the sense signal SENSE of a turn-off level voltage, and the reference voltage V_{ref} supplied from the reference voltage line RVL cannot be supplied to the second node N2 of the driving transistor DRT.

When the sense transistor SENT is an n-type, the turn-on level voltage can be a high-level voltage, and the turn-off level voltage can be a low-level voltage. When the sense transistor SENT is a p-type, the turn-on level voltage can be a low-level voltage, and the turn-off level voltage can be a high-level voltage.

According to one embodiment of the present disclosure, the storage capacitor Cst can be electrically connected between the first node N1 and the second node N2 of the driving transistor DRT to maintain the data voltage Vdata corresponding to an image signal voltage or a voltage corresponding thereto for one frame time.

According to one embodiment of the present disclosure, the storage capacitor Cst can be an external capacitor intentionally designed outside the driving transistor DRT rather than a parasitic capacitor (e.g., Cgs or Cgd) that is an internal capacitor existing between the first node N1 and the second node N2 of the driving transistor DRT.

According to one embodiment of the present disclosure, each of the driving transistor DRT, the scan transistor SCT, and the sense transistor SENT can be an n-type transistor or a p-type transistor. All of the driving transistor DRT, the scan transistor SCT, and the sense transistor SENT can be an n-type transistor or a p-type transistor, but is not limited thereto. At least one of the driving transistor DRT, the scan transistor SCT, and the sense transistor SENT can be an n-type transistor (or a p-type transistor) and the others can be p-type transistors (or n-type transistors).

According to one embodiment of the present disclosure, the scan signal line SCL and the sense signal line SENL can be different gate lines GL. In this case, the scan signal SCAN and the sense signal SENSE can be separate gate signals, and an on-off timing of the scan transistor SCT and an on-off timing of the sense transistor SENT in one sub-pixel SP can be independent, but is not limited thereto. For example, the on-off timing of the scan transistor SCT and the on-off timing of the sense transistor SENT in one sub-pixel SP can be the same or different.

Alternatively, the scan signal line SCL and the sense signal line SENL can be the same gate line GL. For example, the gate node of the scan transistor SCT and the gate node of the sense transistor SENT in one sub-pixel SP can be connected to one gate line GL. In this case, the scan signal SCAN and the sense signal SENSE can be the same gate signals, and the on-off timing of the scan transistor SCT and the on-off timing of the sense transistor SENT in one sub-pixel SP can be the same, but is not limited thereto. That is, the on-off timing of the scan transistor SCT and the on-off timing of the sense transistor SENT in one sub-pixel SP may be the same or different.

According to one embodiment of the present disclosure, the reference voltage line RVL can be disposed in each sub-pixel column.

Alternatively, the reference voltage line RVL can be disposed in every two or more sub-pixel columns. When the reference voltage line RVL can be disposed in every two or more sub-pixel columns, the plurality of sub-pixels SP can receive the reference voltage V_{ref} from one reference voltage line RVL. For example, one reference voltage line RVL can be disposed in every four sub-pixel columns. For example, one reference voltage line RVL can be shared by sub-pixels SP included in four sub-pixel columns.

According to one embodiment of the present disclosure, the driving voltage line DVL can be disposed in every one sub-pixel column.

Alternatively, the driving voltage line DVL can be disposed in every two or more sub-pixel columns. When the driving voltage line DVL is disposed in every two or more sub-pixel columns, the plurality of sub-pixels SP can receive the driving voltage EVDD from one driving voltage line DVL. For example, one driving voltage line DVL can be disposed in every four sub-pixel columns. For example, one driving voltage line DVL can be shared by sub-pixels SP included in four sub-pixel columns.

The 3T1C structure of the sub-pixel SP shown in FIG. 2 is only an example for description and can further include one or more transistors, or in some cases, one or more capacitors. Alternatively, each of the plurality of sub-pixels can have the same structure, or some of the plurality of sub-pixels can have different structures.

Meanwhile, the display apparatus 100 according to the embodiments of the present disclosure can have a top emission structure or a bottom emission structure.

Meanwhile, circuit elements such as the light-emitting element ED and the driving transistor DRT included in each of the plurality of sub-pixels SP can have unique characteristics. For example, each light-emitting element ED can have unique characteristics such as a threshold voltage and the like. Each driving transistor DRT can have unique characteristics such as a threshold voltage, a mobility, etc.

According to one embodiment of the present disclosure, the characteristics of the light-emitting element ED can vary as a driving time of the light-emitting element ED increases. As the driving time of the driving transistor DRT increases, the characteristics of the driving transistor DRT can vary.

According to one embodiment of the present disclosure, the driving times of the plurality of sub-pixels SP can be different. Accordingly, changes in the characteristics of the light-emitting element ED included in each of the plurality of sub-pixels SP can be different. Accordingly, a deviation of characteristics between the light-emitting elements ED can occur. In addition, the changes in the characteristics of the driving transistor DRT included in each of the plurality of sub-pixels SP can be different. Accordingly, a deviation of characteristics between the driving transistors DRT can occur.

The deviation of the characteristics between the light-emitting elements ED or the deviation of the characteristics between the driving transistors DRT can cause a luminance deviation between the sub-pixels SP. Accordingly, the luminance uniformity of the display panel 110 can be lowered, thereby deteriorating image quality.

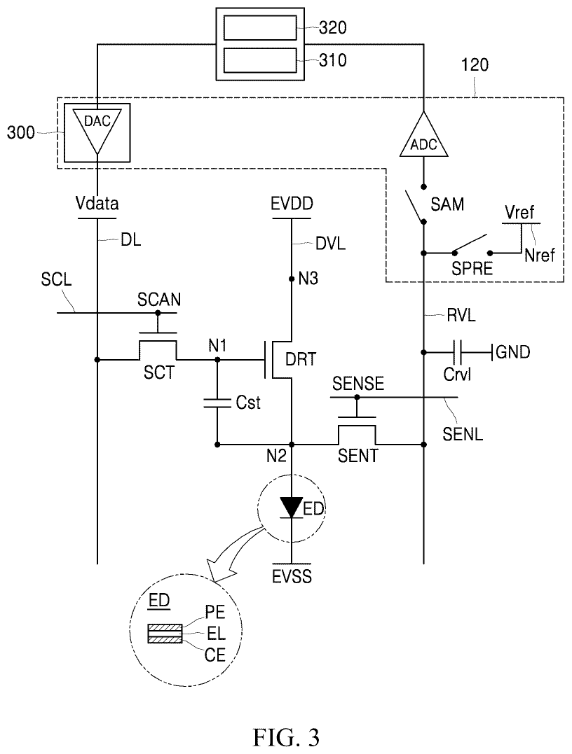

Accordingly, the display apparatus 100 according to the embodiments of the present disclosure can provide a compensation function that reduces the deviation of the characteristics between the light-emitting elements ED or the deviation of the characteristics between the driving transistors DRT and include a compensation circuit therefor. Hereinafter, the compensation function and the compensation circuit will be described with reference to FIG. 3.

FIG. 3 shows a compensation circuit of the display apparatus 100 according to embodiments of the present disclosure.

The compensation circuit of the display apparatus 100 according to the embodiments of the present disclosure is a circuit that can perform sensing and compensation processing for the characteristics of the circuit element in the sub-pixel SP.

Referring to FIG. 3, the compensation circuit can basically include the sub-pixel SP and can include a power switch SPRE, a sampling switch SAM, an analog-to-digital converter ADC, a compensator 320, etc., in order to control the operation of the sub-pixel SP or sense and compensate for the characteristics of the sub-pixel SP (e.g., a threshold voltage of the light-emitting element ED, a threshold voltage of the driving transistor DRT, a mobility, etc.).

The power switch SPRE may be connected between the reference voltage line RVL and a reference voltage application node N_{ref}. According to one embodiment of the present disclosure, the power switch SPRE can control connection between the reference voltage line RVL and a reference voltage application node N_{ref}. The reference voltage V_{ref} output from a power supply device can be supplied to the reference voltage application node N_{ref}, and the reference voltage V_{ref} supplied to the reference voltage application node N_{ref} can be applied to the reference voltage line RVL through the power switch SPRE.

The sampling switch SAM may be connected between the analog-to-digital converter ADC and the reference voltage line RVL. According to one embodiment of the present disclosure, the sampling switch SAM can control connection between the analog-to-digital converter ADC and the reference voltage line RVL. When the analog-to-digital converter ADC is connected to the reference voltage line RVL by the sampling switch SAM, the analog-to-digital converter ADC can convert the voltage (analog voltage) of the connected reference voltage line RVL into a sensing value corresponding to a digital value.

According to one embodiment of the present disclosure, a line capacitor Cᵣᵥₗ can be formed between the reference voltage line RVL and a ground GND. A voltage of the reference voltage line RVL can correspond to the charge amount of the line capacitor Cᵣᵥₗ.

According to one embodiment of the present disclosure, the analog-to-digital converter ADC can provide sensing data including the sensing value to the compensator 320. The compensator 320 can find out the characteristics of the light-emitting element ED or the driving transistor DRT included in the corresponding sub-pixel SP based on the sensing data, calculate a compensation value, and store the compensation value in a memory 310.

For example, the compensation value is information for reducing the deviation of the characteristics between the light-emitting elements ED or the deviation of the characteristics between the driving transistors DRT and can include an offset and gain value for changing data.

According to one embodiment of the present disclosure, the timing controller 140 can change the image data using the compensation value stored in the memory 310 and supply the changed image data to the data driver 120.

According to one embodiment of the present disclosure, the data driver 120 can include a data signal supplier 300 for outputting data signals to a plurality of data lines DL. The data signal supplier 300 can include a latch circuit, a digital-to-analog converter DAC, etc.

According to one embodiment of the present disclosure, the data signal supplier 300 of the data driver 120 can convert the image data changed based on the compensation value into an analog voltage data signal Vdata and output the analog voltage data using the digital-to-analog converter DAC. Accordingly, compensation can be achieved.

The analog-to-digital converter ADC, the power switch SPRE, and the sampling switch SAM can be included in the data driver 120, but is not limited thereto. For example, the data signal supplier 300 for outputting data signals to a plurality of data lines DL may be included in the data driver 120. In addition, the memory 310 and the compensator 320 can be included in the timing controller 140.

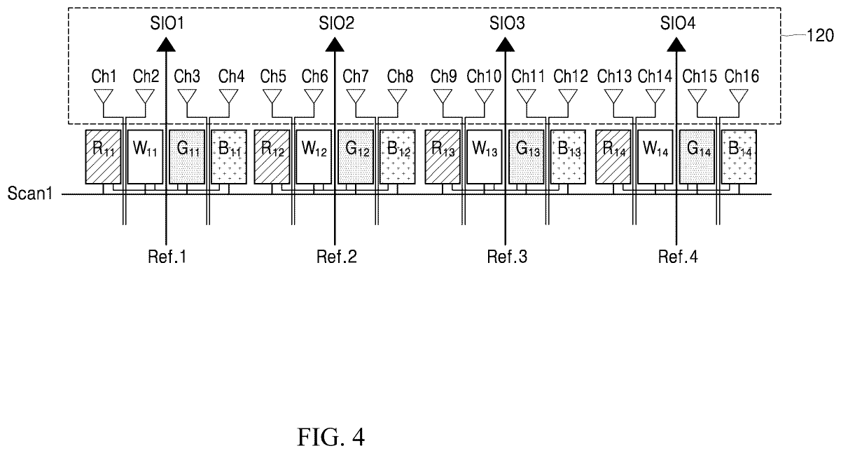

FIG. 4 is a first example view showing a driving method of a display panel according to the embodiments of the present disclosure.

Referring to FIG. 4, the data driver 120 may drive 16 data lines on the basis of one data line, but is not limited thereto.

As one example, the plurality of sub-pixels may include a plurality of first sub-pixels of a first pixel, which share a first reference voltage line Ref.1, and a plurality of second sub-pixels of a second pixel, which share a second reference voltage line Ref.2. The first reference voltage line Ref.1 may supply a reference voltage to the first pixel, and the second reference voltage line Ref.2 may supply a reference voltage to the second pixel.

Referring to FIG. 4, the plurality of sub-pixels can include first sub-pixels R₁₁, W₁₁, G₁₁, and B₁₁ of a first pixel, which share a first reference voltage line Ref.1, and second sub-pixels R₁₂, W₁₂, G₁₂, and B₁₂ of a second pixel, which share a second reference voltage line Ref.2. Likewise, the plurality of sub-pixels can include third sub-pixels R₁₃, W₁₃, G₁₃, and B₁₃ of a third pixel, which share a third reference voltage line Ref.3, and fourth sub-pixels R₁₄, W₁₄, G₁₄, and B₁₄ of a fourth pixel, which share a fourth reference voltage line Ref.4.

In addition, the first reference voltage line Ref.1 is connected to a first sensing channel terminal SIO1, the second reference voltage line Ref.2 is connected to a second sensing channel terminal SIO2, the third reference voltage line Ref.3 is connected to a third sensing channel terminal SIO3, and the fourth reference voltage line Ref.4 is connected to a fourth sensing channel terminal SIO4. In addition, the data driver 120 can obtain a sensing voltage of the corresponding sub-pixel through each sensing channel.

FIG. 4 shows four pixels disposed along one row, but it is obvious that the display panel 110 according to the present disclosure can have a plurality of pixels disposed along a plurality of rows.

For example, the first pixel can include the plurality of first sub-pixels (e.g., a red sub-pixel R₁₁, a white sub-pixel W₁₁, a blue sub-pixel G₁₁, and a green sub-pixel B₁₁). In addition, the second pixel can include the plurality of second sub-pixels (e.g., a red sub-pixel R₁₂, a white sub-pixel W₁₂, a blue sub-pixel G₁₂, and a green sub-pixel B₁₂).

Likewise, the third pixel can include the plurality of third sub-pixels (e.g., a red sub-pixel R₁₃, a white sub-pixel W₁₃, a blue sub-pixel G₁₃, and a green sub-pixel B₁₃). The fourth pixel can include the fourth sub-pixels (e.g., a red sub-pixel R₁₄, a white sub-pixel W₁₄, a blue sub-pixel G₁₄, and a green sub-pixel B₁₄).

According to one embodiment of the present disclosure, each of the first reference voltage line Ref.1 to the fourth reference voltage line Ref.4 can have the power switch SPRE and the sampling switch SAM as shown in FIG. 3.

According to one embodiment of the present disclosure, electrical connection between each reference voltage line (e.g., Ref.1, Ref.2, Ref.3, or Ref.4) and the reference voltage application node N_{ref} can be switched through each power switch SPRE.

For example, electrical connection between each reference voltage line and the analog-to-digital converter ADC can be switched through the sampling switch SAM.

According to one embodiment of the present disclosure, the power switch SPRE and the sampling switch SAM can be included in the data driver 120. In this case, the data driver 120 can include a sensing channel terminal ST to which each reference voltage line is connected.

The first sub-pixels R₁₁, W₁₁, G₁₁, and B₁₁ are described as sharing the first reference voltage line Ref.1. However, according to the present disclosure, the second sub-pixels R₁₂, W₁₂, G₁₂, and B₁₂ can share the second reference voltage line Ref.2, the third sub-pixels R₁₃, W₁₃, G₁₃, and B₁₃ can share the third reference voltage line Ref.3, and the fourth sub-pixels R₁₄, W₁₄, G₁₄, and B₁₄ can share the fourth reference voltage line Ref.4.

In addition, the power switch SPRE and the sampling switch SAM exist on each of the first reference voltage line Ref.1, the second reference voltage line Ref.2, the third reference voltage line Ref.3, and the fourth reference voltage line Ref.4, and electrical connection between each of the reference voltage lines (e.g., Ref.1, Ref.2, Ref.3, and Ref.4) and the reference voltage application node N_{ref} can be switched through each power switch SPRE.

According to one embodiment of the present disclosure, each of the sub-pixels can be connected to each of the data lines. For example, 16 sub-pixels can receive data signals through 16 data lines.

According to one embodiment of the present disclosure, the data driver 120 can be connected to 16 data lines through 16 channel terminals. In addition, the data driver 120 can individually and independently drive each of the data lines. In addition, 16 data channel terminals Ch1, Ch2, Ch3, Ch4, Ch5, Ch6, Ch7, Ch8, Ch9, Ch10, Ch11, Ch12, Ch13, Ch14, Ch15, and Ch16 can be connected to the data signal supplier 300 of the data driver 120.

In addition, one scan signal line Scan1 can be disposed in one sub-pixel line. For example, the 16 sub-pixels can be connected in common to the one scan signal line Scan1. In addition, the 16 sub-pixels can commonly receive a scan signal through the one scan signal line Scan1.

For example, the display apparatus 100 cannot simultaneously perform sensing driving for each of the sub-pixels that share each of the first reference voltage line Ref.1 and the second reference voltage line Ref.2.

According to one embodiment of the present disclosure, the display apparatus 100 cannot simultaneously perform sensing driving for each of a red sub-pixel R₁₁, a white sub-pixel W₁₁, a green sub-pixel G₁₁, and a blue sub-pixel B₁₁ included in the first sub-pixels R₁₁, W₁₁, G₁₁, and B₁₁ that share the first reference voltage line Ref.1.

In addition, the display apparatus 100 cannot simultaneously perform sensing driving for each of a red sub-pixel R₁₂, a white sub-pixel W₁₂, a green sub-pixel G₁₂, and a blue sub-pixel B₁₂ included in the second sub-pixels R₁₂, W₁₂, G₁₂, and B₁₂ that share the second reference voltage line Ref.2.

Likewise, the display apparatus 100 cannot simultaneously perform sensing driving for each of the sub-pixels that share each of the third reference voltage line Ref.3 and the fourth reference voltage line Ref.4.

According to one embodiment of the present disclosure, the 16 sub-pixels can be connected to the 16 data lines, respectively. Therefore, the 16 sub-pixels can receive data signals through corresponding data lines.

According to one embodiment of the present disclosure, the data driver 120 can individually and independently drive the 16 data lines.

The data driver 120 can supply different data signals to the 16 data lines. To this end, the data driver 120 can include 16 data channel terminals connected to the 16 data lines, respectively. The 16 data channel terminals can be connected to the data signal supplier 300.

Referring to FIG. 4, the pixels of the display panel 110 are operated in a single rate driving (SRD) method, a ratio of driving and sensing of each sub-pixel is 16:4 (i.e., 4:1), and the total number of reference compensation times in one scan line is 4 times.

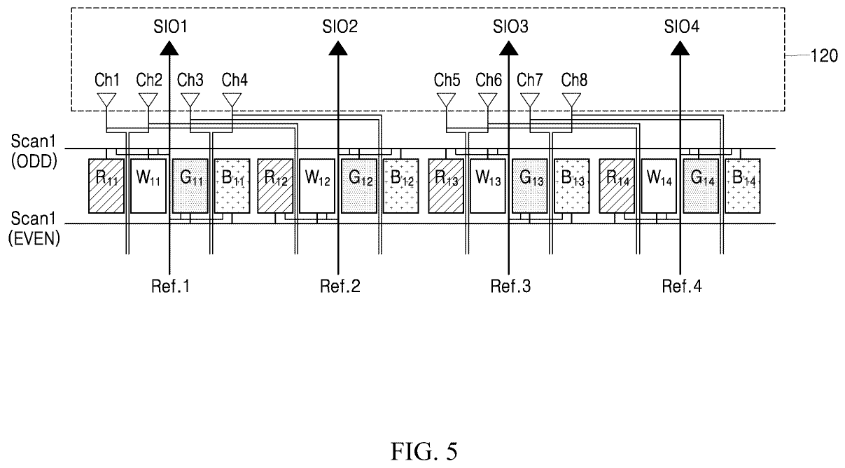

FIG. 5 is a second example view showing a driving method of a display panel according to one embodiment of the present disclosure.

Referring to FIG. 5, the data driver 120 can drive 16 data lines on the basis of 2 data lines.

As one example, the data driver 120 may include a common red data channel terminal Ch1, a common white data channel terminal Ch2, a common green data channel terminal Ch3 and a common blue data channel terminal Ch4.

According to one embodiment of the present disclosure, the data driver 120 can simultaneously drive a data line connected to the red sub-pixel R₁₁ included in the first sub-pixels and a data line connected to the red sub-pixel R₁₂ included in the second sub-pixels. To this end, the data driver 120 can include a common red data channel terminal Ch1 to which the data line connected to the red sub-pixel R₁₁ included in the first sub-pixels and the data line connected to the red sub-pixel R₁₂ included in the second sub-pixels are commonly connected.

In addition, the data driver 120 can simultaneously drive a data line connected to the white sub-pixel W₁₁ included in the first sub-pixels and a data line connected to the white sub-pixel W₁₂ included in the second sub-pixels. To this end, the data driver 120 can include a common white data channel terminal Ch2 to which the data lines are commonly connected. For example, the data line connected to the white sub-pixel W₁₁ included in the first sub-pixels and the data line connected to the white sub-pixel W₁₂ included in the second sub-pixels are commonly connected to the common white data channel terminal Ch2.

In addition, the data driver 120 can simultaneously drive a data line connected to the green sub-pixel G₁₁ included in the first sub-pixels and a data line connected to the green sub-pixel G₁₂ included in the second sub-pixels. To this end, the data driver 120 can include one common green data channel terminal Ch3 to which the data lines are commonly connected. For example, the data line connected to the green sub-pixel G₁₁ included in the first sub-pixels and the data line connected to the green sub-pixel G₁₂ included in the second sub-pixels are commonly connected to the common green data channel terminal Ch3.

In addition, the data driver 120 can simultaneously drive a data line connected to the blue sub-pixel B₁₁ included in the first sub-pixels and a data line connected to the blue sub-pixel B₁₂ included in the second sub-pixels. To this end, the data driver 120 can include a common blue data channel terminal Ch4 to which the data lines are commonly connected. For example, the data line connected to the blue sub-pixel B₁₁ included in the first sub-pixels and the data line connected to the blue sub-pixel B₁₂ included in the second sub-pixels are commonly connected to the common blue data channel terminal Ch4.

When the data driver 120 outputs a data signal to the common red data channel terminal Ch1, the data signal can be supplied to both the data line connected to the red sub-pixel R₁₁ included in the first sub-pixels and the data line connected to the red sub-pixel R₁₂ included in the second sub-pixels.

The data driver 120 can simultaneously drive the data line connected to the white sub-pixel W₁₁ included in the first sub-pixels and the data line connected to the white sub-pixel W₁₂ included in the second sub-pixels.

To this end, the data driver 120 can include one common white data channel terminal Ch2 to which the data line connected to the white sub-pixel W₁₁ included in the first sub-pixels and the data line connected to the white sub-pixel W₁₂ included in the second sub-pixels are commonly connected.

When the data driver 120 outputs a data signal to the common white data channel terminal Ch2, the data signal can be supplied to both the data line connected to the white sub-pixel W₁₁ included in the first sub-pixels and the data line connected to the white sub-pixel W₁₂ included in the second sub-pixels.

The data driver 120 can simultaneously drive the data line connected to the green sub-pixel G₁₁ included in the first sub-pixels and the data line connected to the green sub-pixel G₁₂ included in the second sub-pixels.

To this end, the data driver 120 can include one common green data channel terminal Ch3 to which the data line connected to the green sub-pixel G₁₁ included in the first sub-pixels and the data line connected to the green sub-pixel G₁₂ included in the second sub-pixels are commonly connected.

When the data driver 120 outputs a data signal to the common green data channel terminal Ch3, the data signal can be supplied to both the data line connected to the green sub-pixel G₁₁ included in the first sub-pixels and the data line connected to the green sub-pixel G₁₂ included in the second sub-pixels.

The data driver 120 can simultaneously drive the data line connected to the blue sub-pixel B₁₁ included in the first sub-pixels and the data line connected to the blue sub-pixel B₁₂ included in the second sub-pixels.

To this end, the data driver 120 can include one common blue data channel terminal Ch4 to which the data line connected to the blue sub-pixel B₁₁ included in the first sub-pixels and the data line connected to the blue sub-pixel B₁₂ included in the second sub-pixels are commonly connected.

When the data driver 120 outputs a data signal to the common blue data channel terminal Ch4, the data signal can be supplied to both the data line connected to the blue sub-pixel B₁₁ included in the first sub-pixels and the data line connected to the blue sub-pixel B₁₂ included in the second sub-pixels.

As described above, the common red data channel terminal Ch1, the common white data channel terminal Ch2, the common green data channel terminal Ch3, and the common blue data channel terminal Ch4 can be connected to the data signal supplier 300 of the data driver 120.

In addition, the first reference voltage line Ref.1 is connected to a first sensing channel terminal SIO1, the second reference voltage line Ref.2 is connected to a second sensing channel terminal SIO2, the third reference voltage line Ref.3 is connected to a third sensing channel terminal SIO3, and the fourth reference voltage line Ref.4 is connected to a fourth sensing channel terminal SIO4. In addition, the data driver 120 can obtain a sensing voltage of the corresponding sub-pixel through each sensing channel.

The pixels of the display panel 110 are operated by a double rate driving (DRD) method, a ratio of driving and sensing of each sub-pixel is 8:4 (i.e., 2:1), and the total number of reference compensation times in one scan line is 4 times.

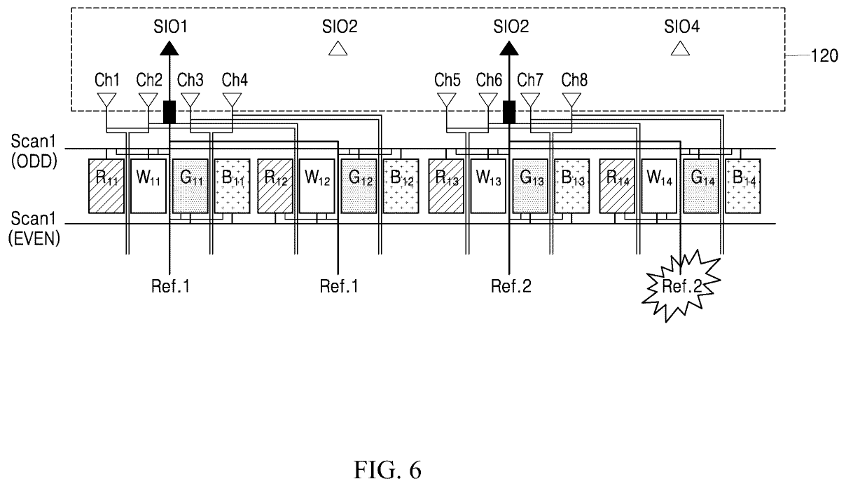

FIG. 6 is a third example view showing a driving method of a display panel according to one embodiment of the present disclosure. For instance, FIG. 6 is the same structure as FIG. 5, except that two reference voltage lines are bundled into one and connected to one sensing channel.

According to one embodiment of the present disclosure, a reference voltage line Ref.1(A) shared by the first sub-pixels R₁₁, W₁₁, G₁₁, and B₁₁ of the first pixel and a reference voltage line Ref.1(B) shared by the second sub-pixels R₁₂, W₁₂, G₁₂, and B₁₂ of the second pixel are bundled to share the source drive IC in the SRD and DRD methods and are connected to the first sensing channel terminal SIO1.

According to one embodiment of the present disclosure, a reference voltage line Ref.2(A) shared by the third sub-pixels R₁₃, W₁₃, G₁₃, and B₁₃ of the third pixel and a reference voltage line Ref.2(B) shared by the fourth sub-pixels R₁₄, W₁₄, G₁₄, and B₁₄ of the fourth pixel are bundled to share the source drive IC in the SRD and DRD methods and are connected to the second sensing channel terminal SIO2.

However, due to the bundled structure of the reference voltage line, when a defect occurs in one reference voltage line (e.g., Ref.2(B)), the same defect also occurs in the connected reference voltage line (e.g., Ref.2(A)).

Referring to FIG. 6, the pixels of the display panel 110 are operated by the SRD and DRD methods, a ratio of driving and sensing in an IC block is 8:2 (i.e., 4:1), a ratio of driving and sensing in a pad part is 8:2 (i.e., 4:1), and the total number of reference compensation times in one scan line is 8 times.

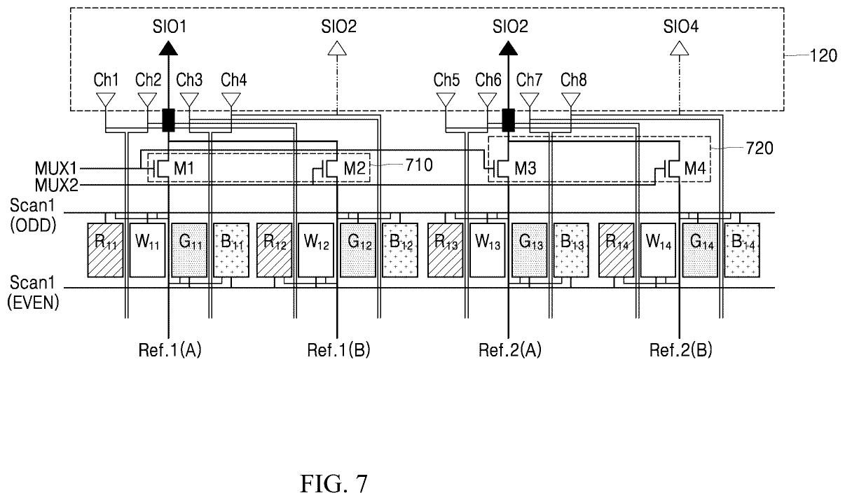

FIG. 7 is a fourth example view showing a plurality of switch elements M1 and M2 added to the driving method of the display panel of FIG. 5.

Referring to FIG. 7, in the data driver 120, the first sensing channel terminal SIO1 can be connected to the reference voltage lines (Ref.1(A) and Ref.1(B)).

Multiplexers 710 and 720 in FIG. 7 is exemplified as 2:1 multiplexers to connect one sensing channel to two reference voltage lines in the data driver 120, but the display panel 110 according to the present disclosure is not limited thereto. For example, each of the multiplexers 710 and 720 can be implemented as a 3:1 multiplexer to connect one sensing channel to three reference voltage lines in the data driver 120. The multiplexers 710 and 720 can be formed directly on the substrate of the display panel 110 or integrated into one drive IC along with the data driver 120.

According to one embodiment of the present disclosure, a first multiplexer 710 can provide sensing values transmitted from the reference voltage lines Ref.1(A) and Ref.1(B) through the first sensing channel terminal SIO1 of the data driver 120 using the switch elements M1 and M2.

In addition, the first switch element M1 is turned on in response to a gate high voltage VGH of a first MUX signal MUX1.

At this time, the sensing value transmitted from the reference voltage line Ref.1(A) is transmitted to the first sensing channel terminal SIO1, and the sensing value transmitted from the reference voltage line Ref.2(A) is transmitted to the second sensing channel terminal SIO2.

According to one embodiment of the present disclosure, a second multiplexer 720 can provide sensing values transmitted from the reference voltage lines Ref.2(A) and Ref.2(B) through the second sensing channel terminal SIO2 of the data driver 120 using the switch elements M1 and M2.

In addition, the second switch element M2 is turned on in response to a gate high voltage VGH of a second MUX signal MUX2.

At this time, the sensing value transmitted from the reference voltage line Ref.1(B) is transmitted to the first sensing channel terminal SIO1, and the sensing value transmitted from the reference voltage line Ref.2(B) is transmitted to the second sensing channel terminal SIO2.

According to one embodiment of the present disclosure, the reference voltage line Ref.1(A) shared by the first sub-pixels R₁₁, W₁₁, G₁₁, and B₁₁ of the first pixel and the reference voltage line Ref.1(B) shared by the second sub-pixels R₁₂, W₁₂, G₁₂, and B₁₂ of the second pixel are bundled to share the source drive IC in the SRD and DRD methods and are connected to the first sensing channel terminal SIO1 in the multiplexer structure.

According to one embodiment of the present disclosure, the reference voltage line Ref.2(A) shared by the third sub-pixels R₁₃, W₁₃, G₁₃, and B₁₃ of the third pixel and the reference voltage line Ref.2(B) shared by the fourth sub-pixels R₁₄, W₁₄, G₁₄, and B₁₄ of the fourth pixel are bundled to share the source drive IC in the SRD and DRD methods and are connected to the second sensing channel terminal SIO2 in the multiplexer structure.

Referring to FIG. 7, the pixels of the display panel 110 are operated by the SRD and DRD methods, a ratio of driving and sensing in the IC block is 8:2 (i.e., 4:1), a ratio of driving and sensing in the pad part is 8:2 (i.e., 4:1), and the total number of reference compensation times in one scan line is 4 times.

The SRD and DRD methods shown in FIGS. 4 and 5 may not share the source drive IC due to the increase in compensation and visibility. For example, it is because, in the SRD method, the ratio of driving and sensing is 4:1 and in the DRD method, the ratio of driving and sensing is 2:1.

In addition, since the SRD and DRD methods shown in FIG. 6 bundle the reference voltage lines Ref.1(A) and Ref.1(B) to share the source drive IC, the compensation time increases by two times, and the degradation of image quality can occur due to a defect in the reference voltage line. For example, visibility can increase because the reference voltage lines Ref.1(A) and Ref.1(B) are bundled.

In addition, the SRD and DRD methods shown in FIG. 7 have a multiplexer structure to share the source drive IC, but a width of a bezel can increase.

As described above, when the display panel 110 is operated by the SRD and DRD methods, there is a limit to sharing the source drive IC because the ratios of the lines of the driving and sensing of the sub-pixels are different. In addition, to share the source drive IC, the sensing channel can be configured as a multiplexer switch or the sensing channel can be bundled and used, but the compensation time and the degradation of image quality due to the increase in the bezel of the data pad part and the bundling of the reference voltage line can increase (e.g., 1 line→2 lines).

Accordingly, to share the source drive IC, it is necessary to configure switches to reduce the sensing time and increase accuracy in a non-pad part in order to prevent the increase in the width of the bezel of the data pad part in the DRD panel structure and separately drive the reference voltage lines to secure the degradation of image quality that is the same level as that of the SRD in terms of performance. In addition, in the SRD method, it is necessary to reduce a cost of the source drive IC by reducing the number of sensing channels. This will be described below.

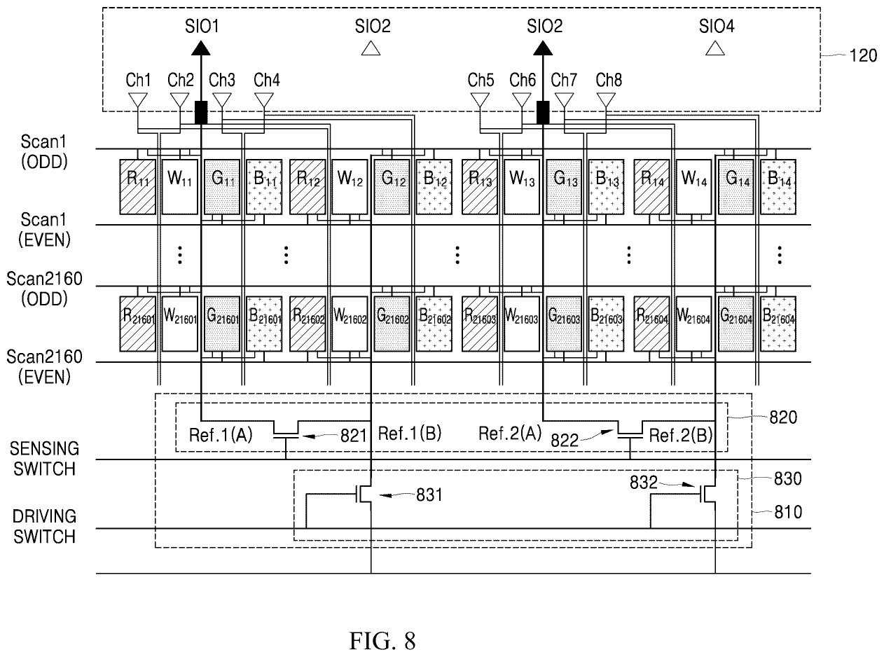

FIG. 8 is a fifth example view showing a driving method of a display panel according to one embodiment of the present disclosure.

Referring to FIG. 8, the data driver 120 can drive 16 data lines on the basis of 2 data lines.

As one example, the data driver 120 may simultaneously drive a data line connected to one of the plurality of sub-pixels included in the first sub-pixels and a data line connected to corresponding one of the plurality of sub-pixels included in the second sub-pixels. To this end, the data driver 120 may include a common data channel terminal to which the data line connected to the one of the plurality of sub-pixels included in the first sub-pixels and the data line connected to corresponding one of the plurality of sub-pixels included in the second sub-pixels are commonly connected.

According to one embodiment of the present disclosure, the data driver 120 can simultaneously drive a data line connected to the red sub-pixel R₁₁ included in the first sub-pixels and a data line connected to the red sub-pixel R₁₂ included in the second sub-pixels. To this end, the data driver 120 can include a common red data channel terminal Ch1 to which the data line connected to the red sub-pixel R₁₁ included in the first sub-pixels and the data line connected to the red sub-pixel R₁₂ included in the second sub-pixels are commonly connected.

In addition, the data driver 120 can simultaneously drive the data line connected to the white sub-pixel W₁₁ included in the first sub-pixels and the data line connected to the white sub-pixel W₁₂ included in the second sub-pixels. To this end, the data driver 120 can include one common white data channel terminal Ch2 to which the data line connected to the white sub-pixel W₁₁ included in the first sub-pixels and the data line connected to the white sub-pixel W₁₂ included in the second sub-pixels are commonly connected.

In addition, the data driver 120 can simultaneously drive the data line connected to the green sub-pixel G₁₁ included in the first sub-pixels and the data line connected to the green sub-pixel G₁₂ included in the second sub-pixels. To this end, the data driver 120 can include one common green data channel terminal Ch3 to which the data line connected to the green sub-pixel G₁₁ included in the first sub-pixels and the data line connected to the green sub-pixel G₁₂ included in the second sub-pixels are commonly connected.

In addition, the data driver 120 can simultaneously drive the data line connected to the blue sub-pixel B₁₁ included in the first sub-pixels and the data line connected to the blue sub-pixel B₁₂ included in the second sub-pixels. To this end, the data driver 120 can include one common blue data channel terminal Ch4 to which the data line connected to the blue sub-pixel B₁₁ included in the first sub-pixels and the data line connected to the blue sub-pixel B₁₂ included in the second sub-pixels are commonly connected.

According to one embodiment of the present disclosure, when the data driver 120 outputs a data signal to the common red data channel terminal Ch1, the output data signal can be supplied to both the data line connected to the red sub-pixel R₁₁ included in the first sub-pixels and the data line connected to the red sub-pixel R₁₂ included in the second sub-pixels.

According to one embodiment of the present disclosure, when the data driver 120 outputs a data signal to the common white data channel terminal Ch2, the data signal can be supplied to both the data line connected to the white sub-pixel W₁₁ included in the first sub-pixels and the data line connected to the white sub-pixel W₁₂ included in the second sub-pixels.

According to one embodiment of the present disclosure, when the data driver 120 outputs a data signal to the common green data channel terminal Ch3, the data signal can be supplied to both the data line connected to the green sub-pixel G₁₁ included in the first sub-pixels and the data line connected to the green sub-pixel G₁₂ included in the second sub-pixels.

According to one embodiment of the present disclosure, when the data driver 120 outputs a data signal to the common blue data channel terminal Ch4, the data signal can be supplied to both the data line connected to the blue sub-pixel B₁₁ included in the first sub-pixels and the data line connected to the blue sub-pixel B₁₂ included in the second sub-pixels.

As described above, the common red data channel terminal Ch1, the common white data channel terminal Ch2, the common green data channel terminal Ch3, and the common blue data channel terminal Ch4 can be connected to the data signal supplier 300 of the data driver 120.

In addition, the first reference voltage line Ref.1 is connected to the first sensing channel terminal SIO1, the second reference voltage line Ref.1 is not connected to the second sensing channel terminal SIO2, the third reference voltage line Ref.3 is connected to the third sensing channel terminal SIO3, and the fourth reference voltage line Ref.4 is not connected to the fourth sensing channel terminal SIO4. In addition, the data driver 120 can obtain a sensing voltage of the corresponding sub-pixel through each sensing channel.

According to one embodiment of the present disclosure, the reference voltage line Ref.1(A) is disposed in sub-pixels of a first column, the reference voltage line Ref.1(B) is disposed in sub-pixels of a second column, the reference voltage line Ref.2(A) is disposed in sub-pixels of a third column, and the reference voltage line Ref.2(B) is disposed in sub-pixels of a fourth column.

According to one embodiment of the present disclosure, the reference voltage line Ref.1(A) is disposed in the sub-pixels of the first column to acquire sensing values of the sub-pixels of the first column and transmit the sensing values to the data driver 120 through the first sensing channel terminal SIO1. In addition, the sub-pixels of the second column in which the reference voltage line Ref.1(B) is disposed are compensated by applying characteristics of the sub-pixels of the first column. In this way, since the characteristics of the sub-pixels of the first column are applied to the compensation values of the sub-pixels of the second column, the reference voltage line Ref.1(B) does not need to be connected to the first sensing channel terminal SIO1.

For example, when the characteristics of the sub-pixels of the first column are not defective, the characteristics of the sub-pixels of the first column are applied to the compensation values of the sub-pixels of the second column.

According to one embodiment of the present disclosure, the reference voltage line Ref.2(A) is disposed in sub-pixels of a third column to acquire sensing values of the sub-pixels of the third column and transmit the sensing values to the data driver 120 through the second sensing channel terminal SIO2. In addition, sub-pixels of a fourth column in which the reference voltage line Ref.2(B) is disposed are compensated by applying characteristics of the sub-pixels of the third column. In this way, since the characteristics of the sub-pixels of the third column are applied to the compensation values of the sub-pixels of the fourth column, the reference voltage line Ref.2(B) does not need to be connected to the second sensing channel terminal SIO2.

For example, when the characteristics of the sub-pixels of the third column are not defective, the characteristics of the sub-pixels of the third column are applied to the compensation values of the sub-pixels of the fourth column.

According to one embodiment of the present disclosure, the display panel 110 can have a switch unit 810 including a plurality of switches disposed on a lower portion of the display area DA (see FIG. 1). For example, the switch unit 810 can be disposed in the non-display area (e.g., a bezel area) of the display panel 110.

According to one embodiment of the present disclosure, the switch unit 810 can include at least one sensing switch 820 and at least one driving switch 830.

For example, the switch unit 810 may be connected to the first reference voltage line Ref.1 and the second reference voltage line Ref.2, perform switching to selectively sense characteristics of sub-pixels of one of the first pixel and the second pixel, and switch a path along which the reference voltage is transmitted to one of the first reference voltage line Ref.1 and the second reference voltage line Ref.2 to separately drive the first reference voltage line Ref.1 and the second reference voltage line Ref.2.

According to one embodiment of the present disclosure, the sensing switch 820 can include a first sensing switch 821 that is connected to the reference voltage line Ref.1(A) that supplies the reference voltage to the first sub-pixels R₁₁, W₁₁, G₁₁, and B₁₁ of the first pixel and the reference voltage line Ref.1(B) that supplies the reference voltage to the second sub-pixels R₁₂, W₁₂, G₁₂, and B₁₂ of the second pixel and performs switching to selectively sense the characteristics of one of the first sub-pixels R₁₁, W₁₁, G₁₁, and B₁₁ and the second sub-pixels R₁₂, W₁₂, G₁₂, and B₁₂.

As one example, the first sensing switch 821 may selectively sense the characteristics of the sub-pixel of one of the first pixel and the second pixel. For example, the first sensing switch 821 may selectively sense the characteristics of one of the first sub-pixels R₁₁, W₁₁, G₁₁, and B₁₁ and the second sub-pixels R₁₂, W₁₂, G₁₂, and B₁₂.

In addition, the sensing switch 820 can include a second sensing switch 822 that is connected to the reference voltage line Ref.2(A) that supplies the reference voltage to the third sub-pixels R₁₃, W₁₃, G₁₃, and B₁₃ of the third pixel and the reference voltage line Ref.2(B) that supplies the reference voltage to the fourth sub-pixels R₁₄, W₁₄, G₁₄, and B₁₄ of the fourth pixel and performs switching to selectively sense the characteristics of one of the third sub-pixels R₁₃, W₁₃, G₁₃, and B₁₃ and the fourth sub-pixels R₁₄, W₁₄, G₁₄, and B₁₄.

As one example, the second sensing switch 822 may selectively sense the characteristics of the sub-pixel of one of the third pixel and the fourth pixel. For example, the second sensing switch 822 may selectively sense the characteristics of one of the third sub-pixels R₁₃, W₁₃, G₁₃, and B₁₃ and the fourth sub-pixels R₁₄, W₁₄, G₁₄, and B₁₄.

According to one embodiment of the present disclosure, the reference voltage line Ref.1(A) supplies the reference voltage to the first sub-pixels R₁₁, W₁₁, G₁₁, and B₁₁ and provides the characteristics sensed from each of the first sub-pixels R₁₁, W₁₁, G₁₁, and B₁₁ to the first channel terminal SIO1.

In addition, the characteristics sensed from each of the first sub-pixels R₁₁, W₁₁, G₁₁, and B₁₁ are transmitted to the timing controller 140 (see FIG. 1) (e.g., the compensator 320 of FIG. 3) through the data driver 120. The timing controller 140 (see FIG. 1) (e.g., the compensator 320 of FIG. 3) identifies the characteristics sensed from each of the first sub-pixels R₁₁, W₁₁, G₁₁, and B₁₁ to calculate compensation values and stores the calculated compensation values in the memory 310 (see FIG. 3).

Thereafter, the timing controller 140 (see FIG. 1) reflects the stored compensation values to compensation values of the second sub-pixels R₁₂, W₁₂, G₁₂, and B₁₂ through the data driver 120.

In this way, the first sensing switch 821 is operated to reflect the characteristics sensed from each of the first sub-pixels R₁₁, W₁₁, G₁₁, and B₁₁ in the compensation values of the second sub-pixels R₁₂, W₁₂, G₁₂, and B₁₂, and the sensing signal is transmitted to the first sensing switch 821 through a sensing line 841.

For example, when the characteristics of the first sub-pixels R₁₁, W₁₁, G₁₁, and B₁₁ of the first pixel of the display panel 110 are not defective, the compensation values based on the characteristics of the first sub-pixels R₁₁, W₁₁, G₁₁, and B₁₁ are applied to the compensation values of the second sub-pixels R₁₂, W₁₂, G₁₂, and B₁₂ of the second pixel. The display panel 110 according to the present disclosure can also apply compensation in an opposite case.

For example, when the characteristics of the first sub-pixels R₁₁, W₁₁, G₁₁, and B₁₁ of the first pixel of the display panel 110 are defective, the reference voltage may be transmitted to the first reference voltage line Ref.1 and the second reference voltage line Ref.2. For example, when the characteristics of the first sub-pixels R₁₁, W₁₁, G₁₁, and B₁₁ of the first pixel of the display panel 110 are defective, the characteristics of the second sub-pixels R₁₂, W₁₂, G₁₂, and B₁₂ of the second pixel may be applied to a compensation value of the first sub-pixels R₁₁, W₁₁, G₁₁, and B₁₁ of the first pixel, but is not limited thereto.

According to one embodiment of the present disclosure, the reference voltage line Ref.2(A) supplies the reference voltage to the third sub-pixels R₁₃, W₁₃, G₁₃, and B₁₃ and provides the characteristics sensed from each of the third sub-pixels R₁₃, W₁₃, G₁₃, and B₁₃ to the second channel terminal SIO2.

In addition, the characteristics sensed from each of the third sub-pixels R₁₃, W₁₃, G₁₃, and B₁₃ are transmitted to the timing controller 140 (see FIG. 3) (e.g., the compensator 320 of FIG. 3) through the data driver 120. The timing controller 140 (see FIG. 1) (e.g., the compensator 320 of FIG. 3) identifies the characteristics sensed from each of the third sub-pixels R₁₃, W₁₃, G₁₃, and B₁₃ to calculate compensation values and stores the calculated compensation values in the memory 310 (see FIG. 3).

Thereafter, the timing controller 140 (see FIG. 1) reflects the stored compensation values to compensation values of the fourth sub-pixels R₁₄, W₁₄, G₁₄, and B₁₄ through the data driver 120.

In this way, the second sensing switch 822 is operated to reflect the characteristics sensed from each of the third sub-pixels R₁₃, W₁₃, G₁₃, and B₁₃ in the compensation values of the fourth sub-pixels R₁₄, W₁₄, G₁₄, and B₁₄, and the sensing signal is transmitted to the second sensing switch 822 through the sensing line 841.

For example, when the characteristics of the third sub-pixels R₁₃, W₁₃, G₁₃, and B₁₃ of the third pixel of the display panel 110 are not defective, the compensation values based on the characteristics of the third sub-pixels R₁₃, W₁₃, G₁₃, and B₁₃ are applied to the compensation values of the fourth sub-pixels R₁₄, W₁₄, G₁₄, and B₁₄ of the fourth pixel. The display panel 110 according to the present disclosure can also apply compensation in an opposite case.

For example, when the characteristics of the third sub-pixels R₁₃, W₁₃, G₁₃, and B₁₃ of the third pixel of the display panel 110 are defective, the characteristics of the fourth sub-pixels R₁₄, W₁₄, G₁₄, and B₁₄ of the fourth pixel may be applied to a compensation value of the third sub-pixels R₁₃, W₁₃, G₁₃, and B₁₃ of the third pixel, but is not limited thereto.

According to one embodiment of the present disclosure, the driving switch 830 can include a first driving switch 831 that switches a path along which the reference voltage is transmitted to one of the first reference voltage line Ref.1(A) and the first reference voltage line Ref.1(B) to separately drive the first reference voltage line Ref.1(A) and the first reference voltage line Ref.1(B) in order to selectively operate the first sub-pixels R₁₁, W₁₁, G₁₁, and B₁₁ of the first pixel and the second sub-pixels R₁₂, W₁₂, G₁₂, and B₁₂ of the second pixel.

In this way, the first driving switch 831 separately drives the first reference voltage line Ref.1(A) and the first reference voltage line Ref.1(B) so that one of the first sub-pixels R₁₁, W₁₁, G₁₁, and B₁₁ and the second sub-pixels R₁₂, W₁₂, G₁₂, and B₁₂ is selectively operated, and the driving signal is transmitted to the first driving switch 831 through a driving line 842.

For example, the first driving switch 831 selectively operates the first sub-pixels R₁₁, W₁₁, G₁₁, and B₁₁ or the second sub-pixels R₁₂, W₁₂, G₁₂, and B₁₂ based on the characteristics of the first sub-pixels R₁₁, W₁₁, G₁₁, and B₁₁ of the first pixel and the second sub-pixels R₁₂, W₁₂, G₁₂, and B₁₂ of the second pixel of the display panel 110, but is not limited thereto.

When the characteristics of at least one of the first sub-pixels R₁₁, W₁₁, G₁₁, and B₁₁ of the first pixel of the display panel 110 are defective, the first sensing switch 821 is turned off so that the first sub-pixels R₁₁, W₁₁, G₁₁, and B₁₁ of the first pixel do not operate, and the first driving switch 831 is turned on so that the second sub-pixels R₁₂, W₁₂, G₁₂, and B₁₂ operate.

In addition, the driving switch 830 can include a second driving switch 832 that switches a path along which the reference voltage is transmitted to one of the second reference voltage line Ref.2(A) and the second reference voltage line Ref.2(B) to separately drive the second reference voltage line Ref.2(A) and the second reference voltage line Ref.2(B) in order to selectively operate the third sub-pixels R₁₃, W₁₃, G₁₃, and B₁₃ of the third pixel and the fourth sub-pixels R₁₄, W₁₄, G₁₄, and B₁₄ of the fourth pixel.

In this way, the second driving switch 832 separately drives the second reference voltage line Ref.2(A) and the second reference voltage line Ref.2(B) so that one of the third sub-pixels R₁₃, W₁₃, G₁₃, and B₁₃ and the fourth sub-pixels R₁₄, W₁₄, G₁₄, and B₁₄ is selectively operated, and the driving signal is transmitted to the second driving switch 832 through the driving line 842.

For example, the second driving switch 832 selectively operates the third sub-pixels R₁₃, W₁₃, G₁₃, and B₁₃ or the fourth sub-pixels R₁₄, W₁₄, G₁₄, and B₁₄ based on the characteristics of the third sub-pixels R₁₃, W₁₃, G₁₃, and B₁₃ of the third pixel and the fourth sub-pixels R₁₄, W₁₄, G₁₄, and B₁₄ of the fourth pixel of the display panel 110, but is not limited thereto.

When the characteristics of at least one of the third sub-pixels R₁₃, W₁₃, G₁₃, and B₁₃ of the third pixel of the display panel 110 are defective, the second sensing switch 822 is turned off so that the third sub-pixels R₁₃, W₁₃, G₁₃, and B₁₃ of the third pixel do not operate, and the second driving switch 832 is turned on so that the fourth sub-pixels R₁₄, W₁₄, G₁₄, and B₁₄ operate.

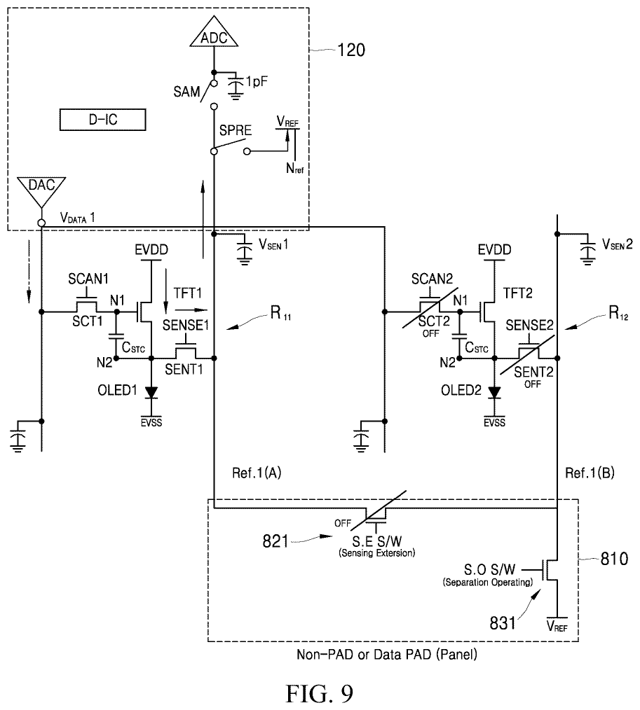

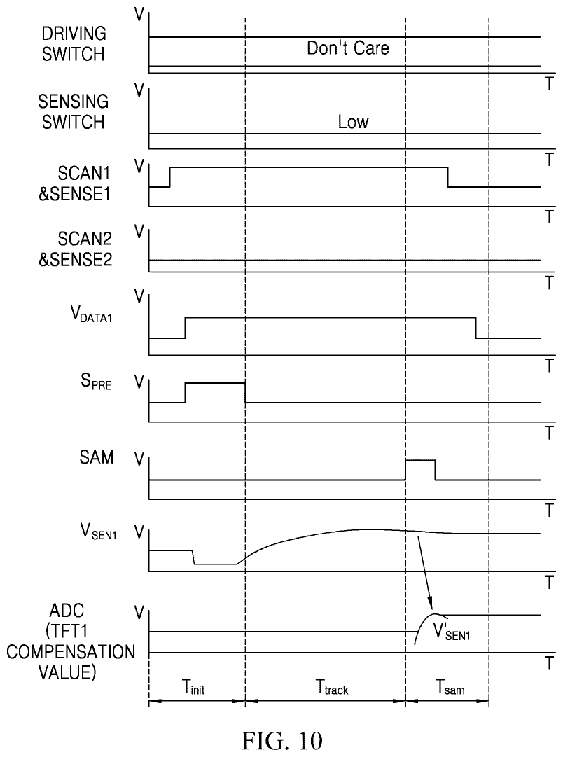

FIG. 9 is a circuit diagram of a first sub-pixel and a second sub-pixel for compensating for a second sub-pixel through characteristics of the first sub-pixel according to one embodiment of the present disclosure. FIG. 10 is a timing diagram for describing sensing driving of the pixel of FIG. 9.

Referring to FIG. 9, the driving operation of each sub-pixel is the same as those described in FIGS. 2 and 3, and the same technical description will be omitted for convenience of description.

According to one embodiment of the present disclosure, the reference voltage V_{ref} output from the power supply device can be supplied to the reference voltage application node N_{ref}, and the reference voltage V_{ref} supplied to the reference voltage application node N_{ref} can be applied to the reference voltage line Ref.1(A) through the power switch SPRE.

According to one embodiment of the present disclosure, the sampling switch SAM can control connection between the analog-to-digital converter ADC and the reference voltage line Ref.1(A). When the analog-to-digital converter ADC is connected to the reference voltage line Ref.1(A) by the sampling switch SAM, the analog-to-digital converter ADC can convert the voltage (analog voltage) of the connected reference voltage line Ref.1(A) into a sensing value corresponding to a digital value.

According to one embodiment of the present disclosure, the analog-to-digital converter ADC can provide sensing data including the sensing value to the compensator 320 (see FIG. 3). The compensator 320 finds out characteristics of a light-emitting element OLED1 or the driving transistor DRT included in the first sub-pixel R₁₁ of the first pixel based on the sensing data, calculates the compensation value, and stores the compensation value in the memory 310. In addition, the compensation value stored in the memory 310 is reflected in the compensation of the first sub-pixel R₁₂ of the second pixel.

To this end, the first sensing switch 821 of the switch unit 810 is turned off to reflect the characteristics sensed from the first sub-pixel R₁₁ of the first pixel in the compensation value of the first sub-pixel R₁₂ of the second pixel. In this case, the first driving switch 831 of the switch unit 810 can be turned on or turned off.

In this way, when the characteristics of the first sub-pixel R₁₁ of the first pixel is not defective, the compensation value based on the characteristics of the first sub-pixel R₁₁ can be applied to the compensation value of the first sub-pixel R₁₂ of the second pixel.

Referring to FIG. 10, to reflect the characteristics sensed from the first sub-pixel R₁₁ of the first pixel in the compensation value of the first sub-pixel R₁₂ of the second pixel, the first driving switch 831 can be turned on or turned off (Don't care), and the first sensing switch 821 is turned off.

In addition, a sensing driving period can include an initialization period Tᵢₙᵢₜ, a tracking period T_{track}, and a sampling period Tₛₐₘ.

The initialization period Tᵢₙᵢₜ of the sensing driving period is a period in which the first node N1 and the second node N2 of the driving transistor DRT are initialized. During the initialization period Tᵢₙᵢₜ, a voltage V1 of the first node N1 of the driving transistor DRT can be initialized by a data signal for sensing driving, and a voltage V2 of the second node N2 of the driving transistor DRT can be initialized by the reference voltage V_{ref} for sensing driving.

The sensing driving data signal is a data signal having a specific voltage value for sensing driving. Usually, the data signal for sensing driving can have a constant voltage value during one sensing driving period.

For example, in a state in which the first sensing switch 821 is turned off, during the initialization period Tᵢₙᵢₜ, a scan transistor SCT1 and a sense transistor SENT1 of the first sub-pixel R₁₁ of the first pixel can be turned on, and the power switch SPRE can be turned on. In contrast, a scan transistor SCT2 and a sense transistor SENT2 of the first sub-pixel R₁₂ of the second pixel are turned off.

Referring to FIG. 10, the tracking period T_{track} of the sensing driving period is a period in which the voltage V2 of the second node N2 of the driving transistor DRT that reflects the threshold voltage (Vₜₕ) of the driving transistor DRT or a change in the threshold voltage is tracked.

During the tracking period T_{track}, the power switch SPRE can be turned on or the sense transistor SENT can be turned on. Accordingly, the second node N2 of the driving transistor DRT can be in a state in which the reference voltage V_{ref} is no longer applied. For example, the second node N2 of the driving transistor DRT can be electrically floated.

During the tracking period T_{track}, the voltage V2 of the second node N2 of the driving transistor DRT can increase, and after a certain amount of time has passed, the voltage V2 may not increase continuously and can be saturated. For example, as the tracking period T_{track} progresses, a voltage increase range of the second node N2 of the driving transistor DRT can decrease, and ultimately, the voltage V2 of the second node N2 of the driving transistor DRT can be saturated.

When the voltage V2 of the second node N2 of the driving transistor DRT is saturated, the sampling period Tₛₐₘ can begin. The sampling period Tₛₐₘ can begin when the sampling switch SAM is turned on.

As one example, to reflect the characteristics sensed from the first sub-pixel R₁₁ of the first pixel in the compensation value of the first sub-pixel R₁₂ of the second pixel, the first sensing switch 821 is turned off when the characteristics of the sub-pixel of the first pixel are not defective.

As described above, to reflect the characteristics sensed from the first sub-pixel R₁₁ of the first pixel in the compensation value of the first sub-pixel R₁₂ of the second pixel, the first driving switch 831 of the switch unit 810 can be turned on or turned off, and the first sensing switch 821 is turned off.

In this way, since the first sensing switch 821 is turned off regardless of the operating state of the first driving switch 831, a sensing voltage V_{SEN1} of the first sub-pixel R₁₁ of the first pixel is generated as a sensing voltage V′_{SEN1} in the sampling period Tₛₐₘ to be applied to the compensation value of the first sub-pixel R₁₂ of the second pixel.

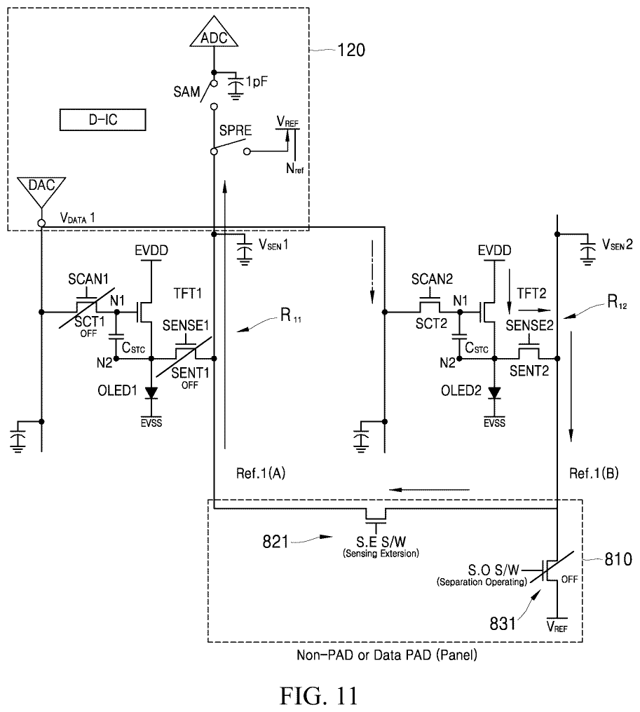

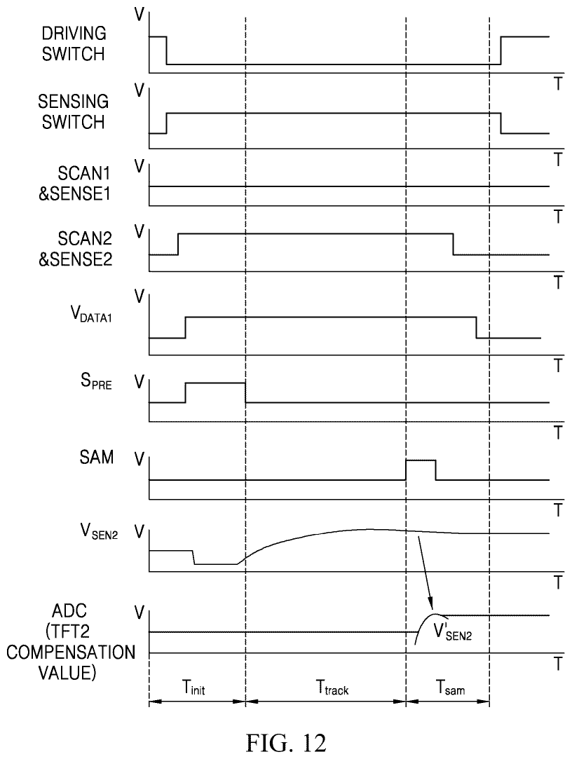

FIG. 11 is a circuit diagram showing additional sensing for the second sub-pixel after compensating for the second sub-pixel through the characteristics of the first sub-pixel according to one embodiment of the present disclosure. FIG. 12 is a timing diagram for describing the sensing driving of the pixel of FIG. 11.

Referring to FIGS. 11 and 12, the driving operation for each sub-pixel is the same as those described in FIGS. 2, 3, and 9, and the same technical description will be omitted for convenience of description.

Since the first sensing switch 821 is turned off regardless of the operating state of the first driving switch 831, the sensing voltage V_{SEN1} of the first sub-pixel R₁₁ of the first pixel is applied to the compensation value of the first sub-pixel R₁₂ of the second pixel.

After the sensing voltage V_{SEN1} of the first sub-pixel R₁₁ of the first pixel is applied to the compensation value of the first sub-pixel R₁₂ of the second pixel, the first sub-pixel R₁₂ of the second pixel is additionally sensed with respect to the reference voltage line Ref.1(B) to improve image quality.

For such additional sensing of the first sub-pixel R₁₂ of the second pixel, the first driving switch 831 is turned off, and the first sensing switch 821 is turned on.

In addition, the scan transistor SCT1 and the sense transistor SENT1 of the first sub-pixel R₁₁ of the first pixel are turned off. In contrast, the scan transistor SCT2 and the sense transistor SENT2 of the first sub-pixel R₁₂ of the second pixel are turned on, and the power switch SPRE is turned off.

In this way, since the first driving switch 831 is turned off and the first sensing switch 821 is turned on, the sensing voltage V_{SEN1} of the first sub-pixel R₁₁ of the first pixel is applied to the compensation value based on a sensing voltage V′_{SEN2} of the first sub-pixel R₁₂ of the second pixel.

As a result, the sensing voltage V_{SEN1} of the first sub-pixel R₁₁ of the first pixel is updated to the compensation value of the first sub-pixel R₁₂ of the second pixel.

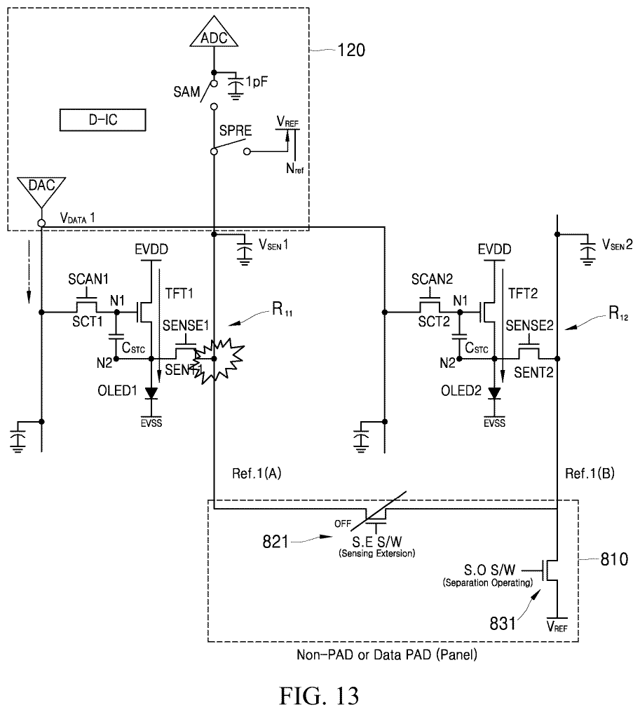

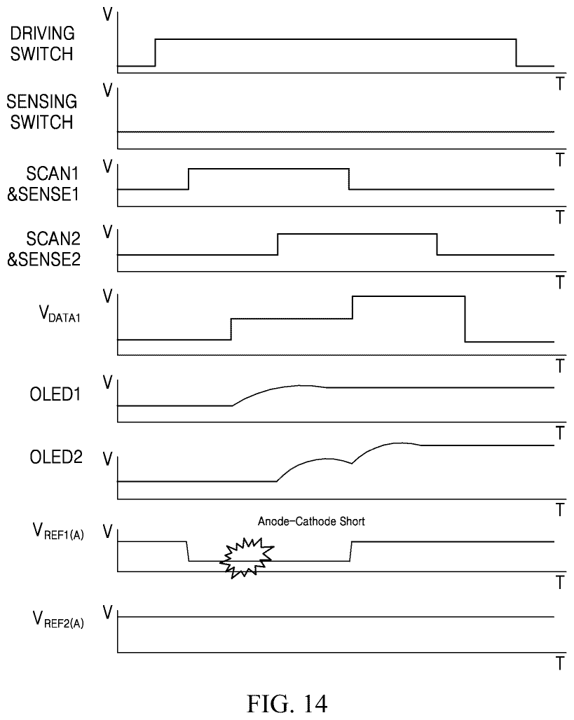

FIG. 13 is a circuit diagram for separately driving a first reference voltage line Ref.1(A) and a first reference voltage line Ref.1(B) when the characteristics of the first sub-pixel is defective according to one embodiment of the present disclosure. FIG. 14 is a timing diagram for describing the sensing driving of the pixel of FIG. 13.

Referring to FIGS. 13 and 14, the driving operation for each sub-pixel is the same as those described in FIGS. 2, 3, and 9, and the same technical description will be omitted for convenience of description.

According to one embodiment of the present disclosure, when a problem occurs in the image quality of the first sub-pixel R₁₁ of the first pixel in which the first reference voltage line Ref.1(A) is disposed (e.g., when the characteristics of the first sub-pixel R₁₁ is defective), the display panel 110 can sense the first sub-pixel R₁₂ of the second pixel through the first reference voltage line Ref.1(B) and compensate for the first sub-pixel R₁₁ of the first pixel. For example, when the characteristics of the first sub-pixel R₁₁ of the first pixel is defective, the sensing switch is switched to ON so as to sense the first sub-pixel R₁₂ of the second pixel.

According to one embodiment of the present disclosure, the first driving switch 831 can separately drive the first reference voltage line Ref.1(A) and the first reference voltage line Ref.1(B) so that one of the first sub-pixels R₁₁, W₁₁, G₁₁, and B₁₁ and the second sub-pixels R₁₂, W₁₂, G₁₂, and B₁₂ is selectively operated. For example, the first driving switch 831 may switch a path along which the reference voltage is transmitted to one of the first reference voltage line Ref.1(A) and the first reference voltage line Ref.1(B) to separately drive the first reference voltage line Ref.1(A) and the first reference voltage line Ref.1(B).

For example, when a defect occurs in the first reference voltage line Ref.1(A) or when a short occurs between an anode electrode and a cathode electrode of the sub-pixel of the first pixel, the second sub-pixels R₁₂, W₁₂, G₁₂, and B₁₂ can be driven by turning on the driving switch 831 through the first reference voltage line Ref.1(B).

In this way, the compensation value based on the characteristics acquired from each of the first sub-pixels R₁₁, W₁₁, G₁₁, and B₁₁ is applied to the compensation value of each of the second sub-pixels R₁₂, W₁₂, G₁₂, and B₁₂.

The display panel 110 according to one embodiment of the present disclosure can include a first pixel including a plurality of sub-pixels, a second pixel disposed at a location adjacent to the first pixel and including a plurality of sub-pixels, a first reference voltage line that supplies a reference voltage to the first pixel, a second reference voltage line that supplies a reference voltage to the second pixel, and a switch unit.

According to one embodiment of the present disclosure, the display panel 110 can further include a sensing line that transmits a sensing signal for sensing characteristics of the first pixel to a sensing switch, and a driving line that transmits a driving signal for separately driving the first reference voltage line and the second reference voltage line to the driving switch.

According to one embodiment of the present disclosure, the switch unit can include at least one sensing switch connected to the first reference voltage line and the second reference voltage line to selectively sense the characteristics of sub-pixels of one of the first pixel and the second pixel, and at least one driving switch that switches a path along which the reference voltage is transmitted to one of the first reference voltage line and the second reference voltage line to separately drive the first reference voltage line and the second reference voltage line.

According to one embodiment of the present disclosure, the switch unit can be disposed in a non-display area (e.g., a bezel area) of the display panel 110.

According to one embodiment of the present disclosure, the sensing switch can maintain an OFF state so that the characteristics of the sub-pixel of the first pixel is applied to a compensation value of the sub-pixel of the second pixel.

According to one embodiment of the present disclosure, the sensing switch can be turned on so that the reference voltage is transmitted to the first reference voltage line and the second reference voltage line when the characteristics of the sub-pixel of the first pixel is defective.

According to one embodiment of the present disclosure, the sensing switch can maintain an ON state so that the characteristics of the sub-pixel of the second pixel is reflected in a compensation value of the first pixel when the characteristics of the sub-pixel of the first pixel is defective.

According to one embodiment of the present disclosure, the driving switch can be switched from ON to OFF when the characteristics of the sub-pixel of the first pixel is defective and the sensing switch is switched from OFF to ON.

According to one embodiment of the present disclosure, when the driving switch is switched from ON to OFF, the characteristics of the second pixel can be applied to the compensation value of the sub-pixel of the first pixel.

According to one embodiment of the present disclosure, the display panel 110 turns on the display panel, then sequentially senses and compensates for the mobility of each sub-pixel of a scan signal line in order to compensate for the mobility and image quality of the sub-pixel, and identifies the type of defect based on a sensing value. In addition, the display panel 110 can be driven by applying an algorithm for each type of defect and applying the compensation value. Likewise, during the driving of the display panel 110, the display panel 110 is driven by sensing and compensating for the mobility of all sub-pixels of a random scan signal line, identifying the type of defect based on the sensing value, applying the algorithm for each type of defect, and applying the compensation value. Thereafter, a threshold voltage of each sub-pixel of the scan signal line is sequentially sensed and compensated, and the type of defect is determined based on the sensing value. In addition, the display panel 110 applies the algorithm for each type of defect and stores the compensation value in a memory. However, when the reference voltage line is defective, degradation of image quality occurs.

Hereinafter, a method of driving a display panel in which the degradation of image quality is prevented from occurring even when the reference voltage is defective according to embodiments of the present disclosure will be described.

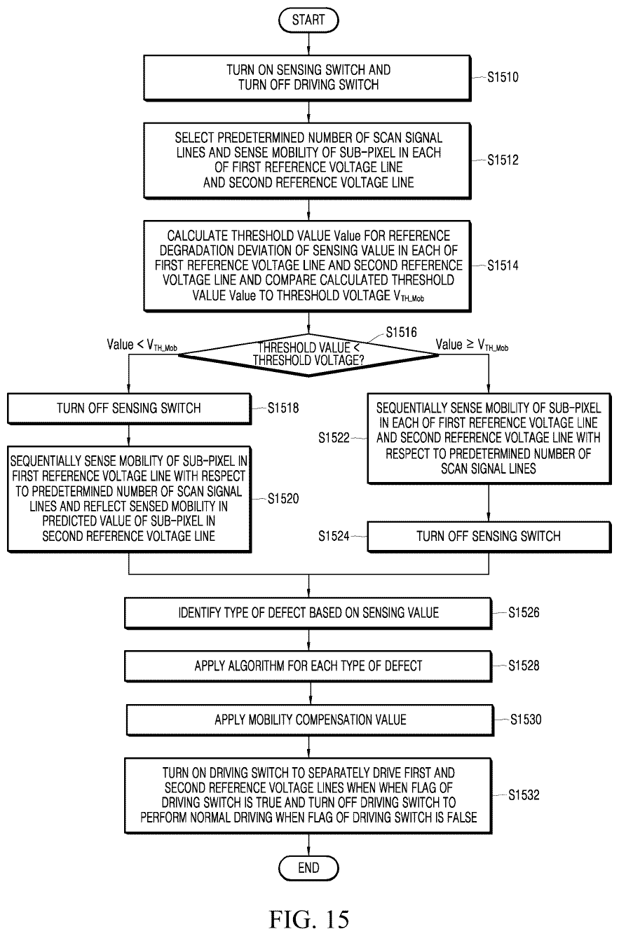

FIG. 15 is a flowchart showing a process of compensating for mobility and image quality of the sub-pixel by turning on a sensing switch after turning on power of the display panel according to one embodiment of the present disclosure.

Hereinafter, referring to FIG. 15, a process of compensating for the mobility and image quality of a sub-pixel by turning on a display panel and then turning on a sensing switch according to an embodiment of the present disclosure will be described in detail as follows.

According to one embodiment of the present disclosure, the display panel 110 can turn on the sensing switch and turn off a driving switch (S1510). The display panel 110 can turn on the sensing switches 821 and 822 (see FIG. 8) and turn off the driving switch to determine a sub-pixel with poor image quality and compensate for the mobility and image quality of the sub-pixel.

According to one embodiment of the present disclosure, the display panel 110 can select a predetermined number of scan signal lines and sense the mobility of the sub-pixel in each of a first reference voltage line and a second reference voltage line (S1512). The display panel 110 can select random scan signal lines (e.g., 1 to 5) from a plurality of scan signal lines disposed on the display panel 110 and sense the mobility of the sub-pixel in each of the first reference voltage line (e.g., Ref.(A)) and the second reference voltage line (e.g., Ref.(B)) for each scan line. For example, the scan signal lines (e.g., 1 to 5) can be randomly selected.

According to one embodiment of the present disclosure, the display panel 110 can calculate a threshold value Value for a degradation deviation based on the sensing value in each of the first reference voltage line and the second reference voltage line and compare the calculated threshold value Value to a magnitude of a threshold voltage V_{TH_Mob} (S1514). The display panel 110 can calculate a threshold value Value A for degradation based on the sensing value of the first reference voltage line (e.g., Ref.(A)) and a threshold value Value B for degradation based on the sensing value of the second reference voltage line (e.g., Ref.(B)). In addition, the display panel 110 can calculate the threshold value (Value=Value A−Value B) for a degradation deviation based on the first reference voltage line (e.g., Ref.(A)) and the second reference voltage line (e.g., Ref.(B)). For example, the display panel 110 may calculate the threshold value (Value=Value A−Value B) by subtracting the threshold value Value B for a degradation deviation based on the second reference voltage line (e.g., Ref.(B)) from the threshold value Value A of the first reference voltage line (e.g., Ref.(A)). In addition, the display panel 110 can compare the size of the calculated threshold value Value to the magnitude of the threshold voltage V_{TH_Mob} based on the mobility.

According to one embodiment of the present disclosure, the display panel 110 can turn off the sensing switch when the threshold value Value is lower than the threshold voltage V_{TH_Mob} (S1516, S1518).

According to one embodiment of the present disclosure, the display panel 110 can sequentially sense the mobility of the sub-pixel in the first reference voltage line with respect to a predetermined number of scan signal lines and reflect the sensed mobility in a predicted value of the sub-pixel in the second reference voltage line (S1520). The display panel 110 can sequentially sense the mobility of the sub-pixel in the first reference voltage line (e.g., Ref.(A)) with respect to each of the predetermined number (e.g., 1 to 5) of scan signal lines after turning off the sensing switch and reflect the sensed mobility in the predicted value of the sub-pixel in the second reference voltage line (e.g., Ref.(B)). For example, the display panel 110 can copy the mobility of the sub-pixel in the first reference voltage line (e.g., Ref.(A)) to the sub-pixel in the second reference voltage line (e.g., Ref.(B)) or apply the above mobility as a weight.

In addition, the display panel 110 can sequentially sense the mobility of the sub-pixel in the first reference voltage line (e.g., Ref.(A)) with respect to the remaining scan signal lines of the display panel and copy the sensed mobility to the sub-pixel in the second reference voltage line (e.g., Ref.(B)) or apply the above mobility as a weight.

According to one embodiment of the present disclosure, when the threshold value Value is higher than or equal to the threshold voltage V_{TH_Mob}, the display panel 110 can sequentially sense the mobility of the sub-pixel in each of the first reference voltage line and the second reference voltage line with respect to the predetermined number of scan signal lines (S1516, S1522). When the threshold value Value calculated in the operation S1514 is higher than or equal to the threshold voltage V_{TH_Mob} based on the mobility, the display panel 110 can sequentially sense the mobility of the sub-pixels in the first reference voltage line (e.g., Ref.(A)) and the second reference voltage line (e.g., Ref.(B)) with respect to each of the predetermined number (e.g., 1 to 5) of scan signal lines.

According to one embodiment of the present disclosure, the display panel 110 can turn off the sensing switch (S1524). The display panel 110 can sequentially sense the mobility of the sub-pixel in the first reference voltage line (e.g., Ref.(A)) with respect to each of a predetermined number (e.g., 1 to 5) of scan signal lines and then turn off the sensing switches 821 and 822.

According to one embodiment of the present disclosure, the display panel 110 can identify the type of defect based on the sensing value (S1526). The display panel 110 can identify the type of defect of the sub-pixel for each of the predetermined number of scan signal lines based on the sensing value.

According to one embodiment of the present disclosure, the display panel 110 can apply an algorithm for each type of defect (S1528). The display panel 110 can apply an algorithm according to the type of defect of the image quality (e.g., bright lines, dark lines, dark spots, etc. for image quality) of the sub-pixel.

According to one embodiment of the present disclosure, the display panel 110 can apply a mobility compensation value (S1530). The display panel 110 can reflect the compensation value based on the mobility of the sub-pixel in the first reference voltage line (e.g., Ref.(A)) in the compensation of the sub-pixel corresponding to the second reference voltage line (e.g., Ref.(B)).

According to one embodiment of the present disclosure, the display panel 110 can turn on the driving switch to separate drive the reference voltage lines when a flag of the driving switch is True and turn off the driving switch to perform normal driving when the flag of the driving switch is False (S1532). The display panel 110 can turn on the driving switches 831 and 832 to separate drive the reference voltage lines when the flag of the driving switch is True and turn off the driving switches 831 and 832 to perform normal driving when the flag of the driving switch is False.

In this way, the display panel 110 according to the present disclosure can determine a sub-pixel with poor image quality by turning on the sensing switch and then separately drive the reference voltage lines using the driving switch, thereby securing the degradation of image quality that is the same level as that of the SRD. For example, the display panel 110 may turn on the sensing switch to sense the mobility of the sub-pixel in each of a first reference voltage line and a second reference voltage line.

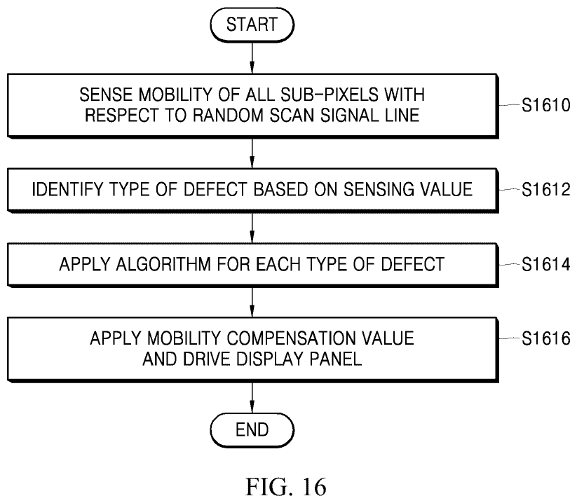

FIG. 16 is a flowchart showing a process of compensating for the mobility and image quality in real time by turning on the sensing switch while the display panel is being driven according to one embodiment of the present disclosure.

Hereinafter, referring to FIG. 16, a process of compensating for mobility and image quality in real time by turning on the sensing switch while the display panel is being driven according to one embodiment of the present disclosure will be described in detail as follows.

According to one embodiment of the present disclosure, the display panel 110 can sense the mobility of all sub-pixels in a random scan signal line (S1610). The display panel 110 can sense the mobility of each of all sub-pixels corresponding to the random scan signal line.

According to one embodiment of the present disclosure, the display panel 110 can identify the type of defect based on the sensing value (S1612). The display panel 110 can determine which sub-pixel has poor image quality and identify the type of defect based on the sensed mobility of each of all sub-pixels.

According to one embodiment of the present disclosure, the display panel 110 can apply an algorithm for each type of defect (S1614). The display panel 110 can apply an algorithm according to the type of defect of the image quality (e.g., bright lines, dark lines, dark spots, etc. for image quality) of the sub-pixel.

According to one embodiment of the present disclosure, the display panel 110 can be driven by applying a mobility compensation value (S1616). The display panel 110 can adjust the compensation value of the sub-pixel with poor image quality in real time based on the sensed mobility of all sub-pixels. Such compensation is performed in each of all sub-pixels according to each scan signal line of the display panel 110.

As described above, the display panel 110 according to the present disclosure can separately drive the reference voltage lines by identifying the sensing of the sub-pixel and the sensing of the data line.

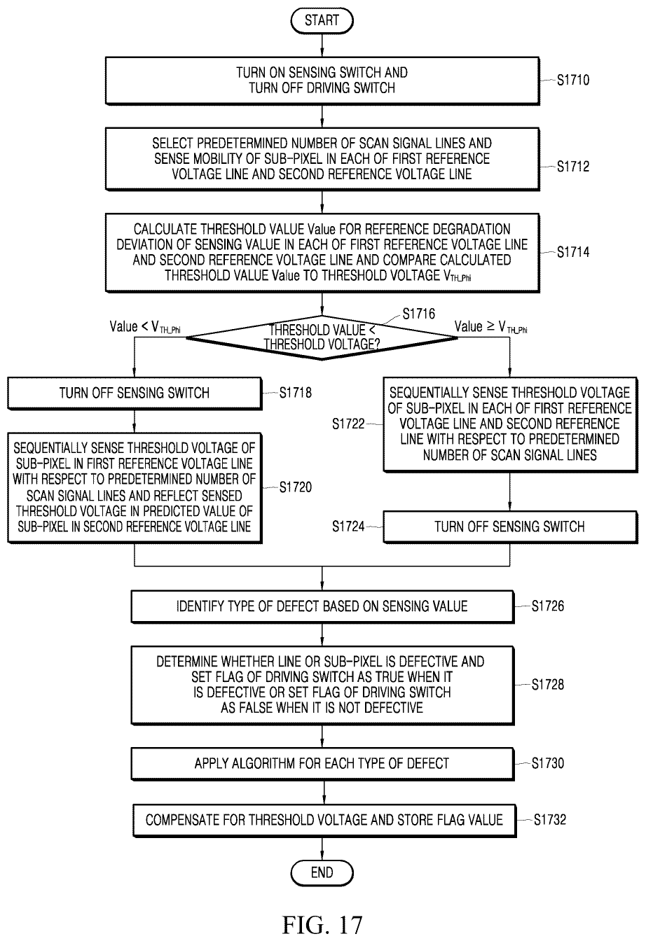

FIG. 17 is a flowchart showing a process of compensating for a threshold voltage and image quality of the sub-pixel after turning off the power of the display panel according to one embodiment of the present disclosure.

Hereinafter, a process of compensating for a threshold voltage and image quality of the sub-pixel after turning off a display panel according to one embodiment of the present disclosure will be described in detail with reference to FIG. 17 as follows.

According to one embodiment of the present disclosure, referring to FIG. 17, the display panel 110 can turn on the sensing switch and turn off the driving switch (S1710). The display panel 110 can turn on the sensing switches 821 and 822 (see FIG. 8) and turn off the driving switch to determine a sub-pixel with poor image quality and compensate for the threshold voltage and image quality of the sub-pixel.

According to one embodiment of the present disclosure, the display panel 110 can select a predetermined number of scan signal lines and sense the threshold voltage of the sub-pixel in each of a first reference voltage line and a second reference voltage line (S1712). The display panel 110 can select random scan signal lines (e.g., 1 to 5) from a plurality of scan signal lines disposed on the display panel 110 and sense the threshold voltage (V_{TH}) of the sub-pixel in each of the first reference voltage line (e.g., Ref.(A)) and the second reference voltage line (e.g., Ref.(B)) with respect to each scan line. For example, the scan signal lines (e.g., 1 to 5) may be randomly selected.

According to one embodiment of the present disclosure, the display panel 110 can calculate a threshold value Value for a degradation deviation based on the sensing value in each of the first reference voltage line and the second reference voltage line and compare the calculated threshold value Value to a magnitude of a threshold voltage V_{TH_Phi} (S1714). The display panel 110 can calculate each of a threshold value Value A for degradation based on the sensing value of the first reference voltage line (e.g., Ref.(A)) and a threshold value Value B for degradation based on the sensing value of the second reference voltage line (e.g., Ref.(B)). In addition, the display panel 110 may calculate a threshold value (Value=Value A−Value B) based on the first reference voltage line (e.g., Ref.(A)) and the second reference voltage line (e.g., Ref.(B)). For example, the display panel 110 can calculate a threshold value (Value=Value A−Value B) obtained by subtracting the threshold value Value B for a degradation deviation based on the second reference voltage line (e.g., Ref.(B)) from the threshold value Value A of the first reference voltage line (e.g., Ref.(A)). In addition, the display panel 110 can compare the size of the calculated threshold value Value to a magnitude of the set threshold voltage V_{TH_Phi}.

According to one embodiment of the present disclosure, the display panel 110 can turn off the sensing switch when the threshold value Value is lower than the threshold voltage V_{TH_Phi} (S1716, S1718).

According to one embodiment of the present disclosure, the display panel 110 can sequentially sense the threshold voltage of the sub-pixel in the first reference voltage line with respect to the predetermined number of scan signal lines and reflect the sensed threshold voltage in a predicted value of the sub-pixel in the second reference voltage line (S1720). The display panel 110 can sequentially sense the threshold voltage of the sub-pixel in the first reference voltage line (e.g., Ref.(A)) with respect to each of the predetermined number (e.g., 1 to 5) of scan signal lines after turning off the sensing switch and reflect the sensed threshold voltage in a predicted value of the sub-pixel in the second reference voltage line (e.g., Ref.(B)). For example, the display panel 110 can copy the threshold voltage of the sub-pixel in the first reference voltage line (e.g., Ref.(A)) to the sub-pixel in the first reference voltage line (e.g., Ref.(A)) or apply the above threshold voltage as a weight.

According to one embodiment of the present disclosure, when the threshold value Value is higher than or equal to the threshold voltage V_{TH_Phi}, the display panel 110 can sequentially sense the threshold voltage of the sub-pixel in each of the first reference voltage line and the second reference voltage line with respect to the predetermined number of scan signal lines (S1716, S1722). When the threshold value Value calculated in the operation S1714 is higher than or equal to the threshold voltage V_{TH_Phi}, the display panel 110 can sequentially sense the threshold voltages of the sub-pixels in the first reference voltage line (e.g., Ref.(A)) and the second reference voltage line (e.g., Ref.(B)) with respect to each of the predetermined number (e.g., 1 to 5) of scan signal lines.

According to one embodiment of the present disclosure, the display panel 110 can turn off the sensing switch (S1724). The display panel 110 can sequentially sense the threshold voltages of the sub-pixels in the first reference voltage line (e.g., Ref.(A)) and the second reference voltage line (e.g., Ref.(B)) with respect to each of the predetermined number (e.g., 1 to 5) of scan signal lines and then turn off the sensing switches 821 and 822.

According to one embodiment of the present disclosure, the display panel 110 can identify the type of defect based on the sensing value (S1726). The display panel 110 can identify the type of defect of the sub-pixel for each of the predetermined number of scan signal lines based on the sensing value.

According to one embodiment of the present disclosure, the display panel 110 can determine whether the line or the sub-pixel is defective, set the flags of the driving switches 831 and 832 as True when the line or the sub-pixel is defective, the display panel 110, or set the flags of the driving switches 831 and 832 as False when the line or the sub-pixel is not defective (S1728). The display panel 110 can set the flags of the driving switches 831 and 832 as True when the line is defective (e.g., defect or the like) or the image quality of the sub-pixel is poor. Alternatively, the display panel 110 can set the flags of the driving switches 831 and 832 as False when the line is not defective (e.g., defect or the like) or the image quality of the sub-pixel is not poor.

According to one embodiment of the present disclosure, the display panel 110 can apply an algorithm for each type of defect (S1730). The display panel 110 can apply an algorithm according to the type of defect of the image quality (e.g., bright lines, dark lines, dark spots, etc. for image quality) of the sub-pixel.

According to one embodiment of the present disclosure, the display panel 110 can compensate for the threshold voltage and store the flag value (S1732). The display panel 110 can compensate for the threshold voltage of the sub-pixel and store the flags (e.g., True or False) of the driving switches 831 and 832 in a NAND memory.

As described above, the display panel 110 according to the present disclosure can determine a sub-pixel with poor image quality by turning on the sensing switch and drive the display panel using the driving switch. Accordingly, it is possible to compensate for the image quality of the display panel 110.

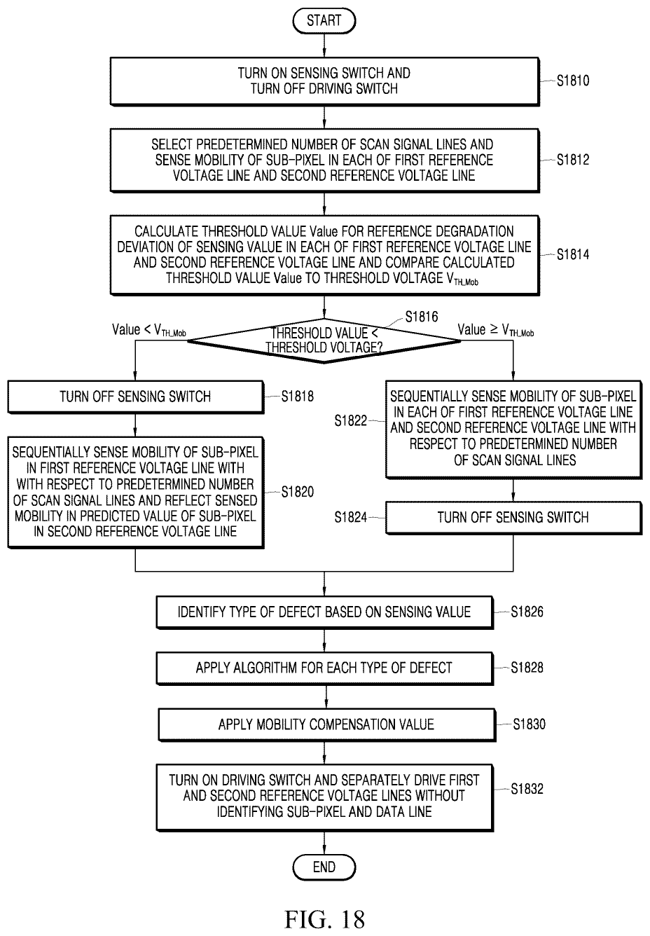

FIG. 18 is a flowchart showing a process of compensating for the mobility and image quality of the sub-pixel by turning on the sensing switch of the display panel and turning off a driving switch of the display panel according to one embodiment of the present disclosure.

Hereinafter, a process of compensating for the mobility and image quality of a sub-pixel after turning on a sensing switch of a display panel and turning off a driving switch of the display panel according to one embodiment of the present disclosure will be described in detail with reference to FIG. 18 as follows.

According to one embodiment of the present disclosure, referring to FIG. 18, the display panel 110 can turn on the sensing switch and turn off the driving switch (S1810). The display panel 110 can turn on the sensing switches 821 and 822 (see FIG. 8) and turn off the driving switch to determine a sub-pixel with poor image quality and compensate for the mobility and image quality of the sub-pixel.

According to one embodiment of the present disclosure, the display panel 110 can select a predetermined number of scan signal lines and sense the mobility of the sub-pixel in each of a first reference voltage line and a second reference voltage line (S1812). The display panel 110 can select random scan signal lines (e.g., 1 to 5) from a plurality of scan signal lines disposed on the display panel 110 and sense the mobility of the sub-pixel in each of the first reference voltage line (e.g., Ref.(A)) and the second reference voltage line (e.g., Ref.(B)) for each scan line. For example, the scan signal lines (e.g., 1 to 5) can be randomly selected.

According to one embodiment of the present disclosure, the display panel 110 can calculate a threshold value Value for a degradation deviation based on the sensing value in each of the first reference voltage line and the second reference voltage line and compare the calculated threshold value Value to a magnitude of a threshold voltage V_{TH_Mob} (S1814). The display panel 110 can calculate each of a threshold value Value A for degradation based on the sensing value of the first reference voltage line (e.g., Ref.(A)) and a threshold value Value B for degradation based on the sensing value of the second reference voltage line (e.g., Ref.(B)). In addition, the display panel 110 can calculate the threshold value (Value=Value A−Value B) for a degradation deviation based on the first reference voltage line (e.g., Ref.(A)) and the second reference voltage line (e.g., Ref.(B)). For example, the display panel 110 may calculate the threshold value (Value=Value A−Value B) obtained by subtracting the threshold value Value B for a degradation deviation based on the second reference voltage line (e.g., Ref.(B)) from the threshold value Value A of the first reference voltage line (e.g., Ref.(A)). In addition, the display panel 110 can compare the size of the calculated threshold value Value to the magnitude of the threshold voltage V_{TH_Mob} based on the mobility.

According to one embodiment of the present disclosure, the display panel 110 can turn off the sensing switch when the threshold value Value is lower than the threshold voltage V_{TH_Mob} (S1816, S1818).

According to one embodiment of the present disclosure, the display panel 110 can sequentially sense the mobility of the sub-pixel in the first reference voltage line with respect to a predetermined number of scan signal lines and reflect the sensed mobility in a predicted value of the sub-pixel in the second reference voltage line (S1820). The display panel 110 can sequentially sense the mobility of the sub-pixel in the first reference voltage line (e.g., Ref.(A)) after turning off the sensing switch and reflect the sensed mobility in the predicted value of the sub-pixel in the second reference voltage line (e.g., Ref.(B)) with respect to each of the predetermined number (e.g., 1 to 5) of scan signal lines of the display panel. For example, the display panel 110 can copy the mobility in the sub-pixel in the first reference voltage line (e.g., Ref.(A)) to the sub-pixel in the second reference voltage line (e.g., Ref.(B)) or apply the above mobility as a weight.

In addition, the display panel 110 can sequentially sense the mobility of the sub-pixel in the first reference voltage line (e.g., Ref.(A)) with respect to the remaining scan signal lines of the display panel and copy the sensed mobility to the sub-pixel in the second reference voltage line (e.g., Ref.(B)) or apply the above mobility as a weight.

According to one embodiment of the present disclosure, when the threshold value Value is higher than or equal to the threshold voltage V_{TH_Mob}, the display panel 110 can sequentially sense the mobility of the sub-pixel in each of the first reference voltage line and the second reference voltage line with respect to a predetermined number of scan signal lines (S1816, S1822). When the threshold value Value calculated in the operation S1514 is higher than or equal to the threshold voltage V_{TH_Mob} based on the mobility, the display panel 110 can sequentially sense the mobility of the sub-pixels in the first reference voltage line (e.g., Ref.(A)) and the second reference voltage line (e.g., Ref.(B)) with respect to each of the predetermined number (e.g., 1 to 5) of scan signal lines.

According to one embodiment of the present disclosure, the display panel 110 can turn off the sensing switch (S1824). The display panel 110 can sequentially sense the mobility of the sub-pixel in the first reference voltage line (e.g., Ref.(A)) with respect to each of the predetermined number (e.g., 1 to 5) of scan signal lines and then turn off the sensing switches 821 and 822.

According to one embodiment of the present disclosure, the display panel 110 can identify the type of defect based on the sensing value (S1826). The display panel 110 can identify the type of defect of the sub-pixel for each of the predetermined number of scan signal lines based on the sensing value.

According to one embodiment of the present disclosure, the display panel 110 can apply an algorithm for each type of defect (S1828). The display panel 110 can apply an algorithm according to the type of defect of the image quality (e.g., bright lines, dark lines, dark spots, etc. for image quality) of the sub-pixel.

According to one embodiment of the present disclosure, the display panel 110 can apply a mobility compensation value (S1830). The display panel 110 can reflect the compensation value based on the mobility of the sub-pixel in the first reference voltage line (e.g., Ref.(A)) in the compensation of the sub-pixel corresponding to the second reference voltage line (e.g., Ref.(B)).

According to one embodiment of the present disclosure, the display panel 110 can turn on the driving switch and separately drive the reference voltage lines (S1832). The display panel 110 can turn on the driving switch to separately drive the reference voltage lines without detecting the sub-pixel and identifying the data line.

In this way, the display panel 110 according to the present disclosure can turn on the sensing switches 821 and 822, turn off the driving switches 831 and 832, determine the sub-pixel with poor image quality, and turn off the sensing switches 821 and 822 to separately drive the reference voltage lines without detecting the sub-pixel and the data line, thereby securing the image quality that is the same level as that of the SRD.

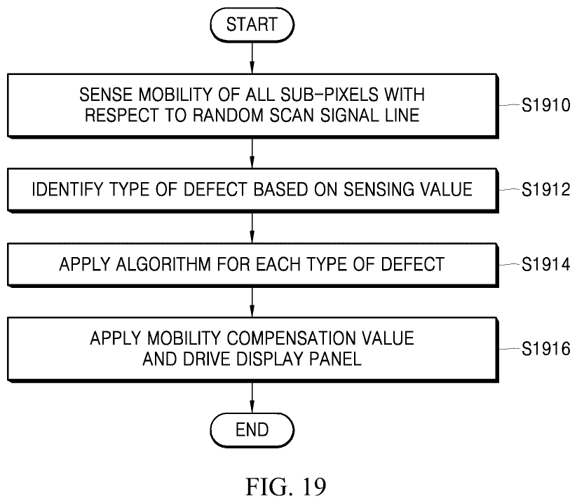

FIG. 19 is a flowchart showing a process of compensating for the mobility and image quality in real time by turning on the sensing switch while the display panel is being driven according to one embodiment of the present disclosure.

Hereinafter, a process of compensating for mobility and image quality in real time by turning on the sensing switch while the display panel is being driven according to one embodiment of the present disclosure will be described in detail with reference to FIG. 19 as follows.

According to one embodiment of the present disclosure, referring to FIG. 19, the display panel 110 can sense the mobility of all sub-pixels in a random scan signal line (S1910). The display panel 110 can sense the mobility of each of all sub-pixels corresponding to the random scan signal line.

According to one embodiment of the present disclosure, the display panel 110 can identify the type of defect based on the sensing value (S1912). The display panel 110 can determine which sub-pixel has poor image quality and identify the type of defect based on the sensed mobility of each of all sub-pixels.

According to one embodiment of the present disclosure, the display panel 110 can apply an algorithm for each type of defect (S1914). The display panel 110 can apply an algorithm according to the type of defect of the image quality (e.g., bright lines, dark lines, dark spots, etc. for image quality) of the sub-pixel.

According to one embodiment of the present disclosure, the display panel 110 can be driven by applying a mobility compensation value (S1916). The display panel 110 can adjust the compensation value of the sub-pixel with poor image quality in real time based on the sensed mobility of all sub-pixels. Such compensation is performed in each of all sub-pixels according to each scan signal line of the display panel 110.

As described above, the display panel 110 according to the present disclosure can separately drive the reference voltage lines at all times without identifying the sensing of the sub-pixel and the sensing of the data line.

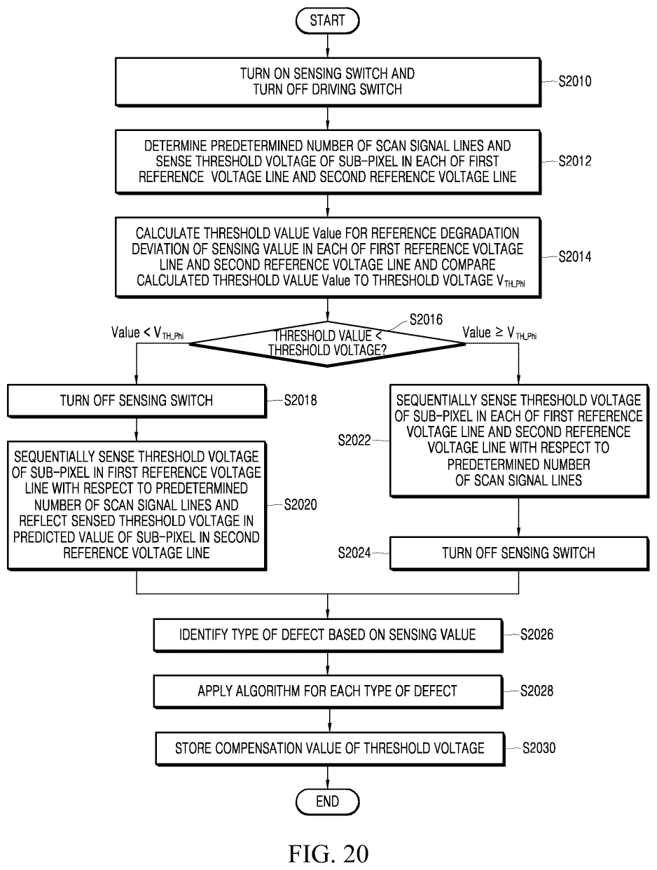

FIG. 20 is a flowchart showing a process of compensating for a threshold voltage and image quality of the sub-pixel after turning off the power of the display panel according to one embodiment of the present disclosure.

Hereinafter, a process of compensating for a threshold voltage and image quality of the sub-pixel after turning off a display panel according to one embodiment of the present disclosure will be described in detail with reference to FIG. 20 as follows.

According to one embodiment of the present disclosure, referring to FIG. 20, the display panel 110 can turn on the sensing switch and turn off the driving switch (S2010). The display panel 110 can turn on the sensing switches 821 and 822 (see FIG. 8) and turn off the driving switch to determine a sub-pixel with poor image quality and compensate for the threshold voltage and image quality of the sub-pixel.

According to one embodiment of the present disclosure, the display panel 110 can select a predetermined number of scan signal lines and sense the threshold voltage of the sub-pixel in each of a first reference voltage line and a second reference voltage line (S2012). The display panel 110 can select random scan signal lines (e.g., 1 to 5) from a plurality of scan signal lines disposed on the display panel 110 and sense the threshold voltage (V_{TH}) of the sub-pixel in each of the first reference voltage line (e.g., Ref.(A)) and the second reference voltage line (e.g., Ref.(B)) with respect to each scan line.

According to one embodiment of the present disclosure, the display panel 110 can calculate a threshold value Value for a degradation deviation based on the sensing value in each of the first reference voltage line and the second reference voltage line and compare the calculated threshold value Value to a magnitude of a threshold voltage V_{TH_Phi} (S2014). The display panel 110 can calculate each of a threshold value Value A for degradation based on the sensing value of the first reference voltage line (e.g., Ref.(A)) and a threshold value Value B for degradation based on the sensing value of the second reference voltage line (e.g., Ref.(B)). In addition, the display panel 110 can calculate a threshold value (Value=Value A−Value B) obtained by subtracting the threshold value Value B for a degradation deviation based on the second reference voltage line (e.g., Ref.(B)) from the threshold value Value A of the first reference voltage line (e.g., Ref.(A)). In addition, the display panel 110 can compare the size of the calculated threshold value Value to a magnitude of the set threshold voltage V_{TH_Phi}.

According to one embodiment of the present disclosure, the display panel 110 can turn off the sensing switch when the threshold value Value is lower than the threshold voltage V_{TH_Phi} (S2016, S2018).

According to one embodiment of the present disclosure, the display panel 110 can sequentially sense the threshold voltage of the sub-pixel in the first reference voltage line with respect to the predetermined number of scan signal lines and reflect the sensed threshold voltage in a predicted value of the sub-pixel in the second reference voltage line (S2020). The display panel 110 can sequentially sense the threshold voltage of the sub-pixel in the first reference voltage line (e.g., Ref.(A)) with respect to each of the predetermined number (e.g., 1 to 5) of scan signal lines after turning off the sensing switch and reflect the sensed threshold voltage in a predicted value of the sub-pixel in the second reference voltage line (e.g., Ref.(B)). For example, the display panel 110 can copy the threshold voltage of the sub-pixel in the first reference voltage line (e.g., Ref.(A)) to the sub-pixel in the first reference voltage line (e.g., Ref.(A)) or apply the above threshold voltage as a weight.

According to one embodiment of the present disclosure, when the threshold value Value is higher than or equal to the threshold voltage V_{TH_Phi}, the display panel 110 can sequentially sense the threshold voltage of the sub-pixel in each of the first reference voltage line and the second reference voltage line with respect to the predetermined number of scan signal lines (S2016, S2022). When the threshold value Value calculated in the operation S1714 is higher than or equal to the threshold voltage V_{TH_Phi}, the display panel 110 can sequentially sense the threshold voltages of the sub-pixels in the first reference voltage line (e.g., Ref.(A)) and the second reference voltage line (e.g., Ref.(B)) with respect to each of the predetermined number (e.g., 1 to 5) of scan signal lines.

According to one embodiment of the present disclosure, the display panel 110 can turn off the sensing switch (S2024). The display panel 110 can sequentially sense the threshold voltages of the sub-pixels in the first reference voltage line (e.g., Ref.(A)) and the second reference voltage line (e.g., Ref.(B)) with respect to each of the predetermined number (e.g., 1 to 5) of scan signal lines and then turn off the sensing switches 821 and 822.

According to one embodiment of the present disclosure, the display panel 110 can identify the type of defect based on the sensing value (S2026). The display panel 110 can identify the type of defect of the sub-pixel for each of the predetermined number of scan signal lines based on the sensing value.

According to one embodiment of the present disclosure, the display panel 110 can apply an algorithm for each type of defect (S2028). The display panel 110 can apply an algorithm according to the type of defect of the image quality (e.g., bright lines, dark lines, dark spots, etc. for image quality) of the sub-pixel.

According to one embodiment of the present disclosure, the display panel 110 can store the compensation value of the threshold voltage (S2030). The display panel 110 can store the compensation value of the threshold voltage of the sub-pixel in the NAND memory.

As described above, the display panel 110 according to the present disclosure can determine a sub-pixel with poor image quality by turning on the sensing switch and drive the display panel using the driving switch. Accordingly, it is possible to compensate for the image quality of the display panel 110.

According to one embodiment of the present disclosure, a method of driving a display apparatus according to the present disclosure can include a first process of performing, by a sensing switch, switching to selectively sense characteristics of sub-pixels of one of a first pixel and a second pixel, and a second process of switching, by a sensing switch, a path along which a reference voltage is transmitted to one of a first reference voltage line and a second reference voltage line to separately drive the first reference voltage line and the second reference voltage line among a plurality of reference voltage lines.

According to one embodiment of the present disclosure, the first process can include a process of turning on a sensing switch so that the reference voltage is transmitted to the first reference voltage line and the second reference voltage line when the characteristics of the sub-pixel of the first pixel is defective.

According to one embodiment of the present disclosure, the second process can include a process of reflecting characteristics of the sub-pixel of the second pixel in a compensation value of the sub-pixel of the first pixel while the sensing switch maintains the ON state, and a process of separately driving the first reference voltage line and the second reference voltage line by switching the driving switch from ON to OFF when the sensing switch is switched from OFF to ON.

As described above, since the display panel 110 according to the present disclosure can sense the characteristics of the first sub-pixel (e.g., R₁₁) of the first pixel through the sensing switch 821 and reflects the sensed characteristics in the compensation value of the first sub-pixel (e.g., R₁₂) of the second pixel or sense the characteristics of the first sub-pixel (e.g., R₁₂) of the second pixel and reflects the sensed characteristics in the compensation value of the first sub-pixel (e.g., R₁₁) of the first pixel, it is possible to share the source drive IC and reduce the cost by reducing the number of sensing channels.

In addition, since the display panel 110 according to the present disclosure can design two reference voltage lines (e.g., Ref.1(A) and Ref.1(B)) in a single bundle structure through the driving switch 831 and switching the path along which the reference voltage is transmitted to one of the first reference voltage line disposed in the first pixel or the second reference voltage line disposed in the second pixel, it is possible to shorten the compensation time and improve image quality.

In addition, since the display panel 110 according to the present disclosure arranges the switching unit including at least one sensing switch and at least one driving switch in the non-display area (e.g., the bezel area or the edge area) of the display panel 110, it is possible to prevent an increase in the width of the bezel of the data pad part.

Although the embodiments of the present disclosure have been described in more detail with reference to the accompanying drawings, the present disclosure is not necessarily limited to these embodiments, and various modifications can be carried out without departing from the technical spirit of the present disclosure. Accordingly, the embodiments disclosed in the present disclosure are not intended to limit the technical spirit of the present disclosure, but is intended to describe the same, and the scope of the technical spirit of the present disclosure is not limited by these embodiments. Accordingly, it should be understood that the above-described embodiments are illustrative and not restrictive in all aspects. The scope of the present disclosure should be construed according to the appended claims, and all technical spirits within the equivalent range should be construed as being included in the scope of the present disclosure.

DESCRIPTION OF REFERENCE NUMERALS

| | |
|---|---|
| 100: display apparatus | 110: display panel |
| 120: data driver | 130: gate driver |
| 140: timing controller | 150: light-emitting element |
| PX: light-emitting element | SP: sub-pixel |
| R: first sub-pixel | W: second sub-pixel |
| B: third sub-pixel | G: fourth sub-pixel |
| DL: data line | GL: gate line |
| DA: display area | NDA: non-display area |

What is claimed is:

1. A display panel comprising:
a first pixel including a plurality of sub-pixels;
a second pixel disposed at a location adjacent to the first pixel and including a plurality of sub-pixels;
a first reference voltage line that supplies a reference voltage to the first pixel;
a second reference voltage line that supplies a reference voltage to the second pixel; and
a switch unit that is connected to the first reference voltage line and the second reference voltage line, performs switching to selectively sense characteristics of a sub-pixel of one of the first pixel and the second pixel, and switches a path along which the reference voltage is transmitted to one of the first reference voltage line and the second reference voltage line to separately drive the first reference voltage line and the second reference voltage line.

2. The display panel of claim 1, wherein the switch unit comprises:
a sensing switch that selectively senses the characteristics of the sub-pixel of one of the first pixel and the second pixel; and
a driving switch that separately drives the first reference voltage line and the second reference voltage line.

3. The display panel of claim 2, wherein the sensing switch maintains an OFF state, so that the characteristics of the sub-pixel of the first pixel is applied to a compensation value of the sub-pixel of the second pixel.

4. The display panel of claim 3, wherein the sensing switch maintains an OFF state so that the characteristics of the sub-pixel of the first pixel is applied to a compensation value of the sub-pixel of the second pixel when the characteristics of the sub-pixel of the first pixel are not defective.

5. The display panel of claim 4, wherein after the characteristics of the sub-pixel of the first pixel is applied to the compensation value of the sub-pixel of the second pixel, the sensing switch is turned on and the driving switch is turned off to sense the characteristics of the sub-pixel of the second pixel.

6. The display panel of claim 2, wherein the sensing switch is switched to ON, so that the reference voltage is transmitted to the first reference voltage line and the second reference voltage line when the characteristics of the sub-pixel of the first pixel are defective.

7. The display panel of claim 6, wherein the sensing switch maintains an ON state, so that the characteristics of the sub-pixel of the second pixel is applied to a compensation value of the sub-pixel of the first pixel when the characteristics of the sub-pixel of the first pixel are defective.

8. The display panel of claim 7, wherein the driving switch is switched from ON to OFF when the characteristics of the sub-pixel of the first pixel are defective and the sensing switch is switched from OFF to ON.

9. The display panel of claim 8, wherein, the first reference voltage line and the second reference voltage line are separately driven when the driving switch is switched from ON to OFF.

10. The display panel of claim 9, wherein, the characteristics of the sub-pixel of the second pixel is applied to the compensation value of the sub-pixel of the first pixel when the driving switch is switched from ON to OFF.

11. The display panel of claim 1, wherein the switch unit is disposed in a non-display area of the display panel.

12. The display panel of claim 2, further comprising:
a sensing line that transmits a sensing signal for sending the characteristics of the sub-pixel of the first pixel, to the sensing switch; and
a driving line that transmits a driving signal for separately driving the first reference voltage line and the second reference voltage line, to the driving switch.

13. A display apparatus comprising:
a display panel including the display panel of claim 1;
a data driver that supplies a data voltage to the display panel through a plurality of data lines; and
a gate driver that supplies a gate signal to the display panel through a plurality of gate lines.

14. The display apparatus of claim 13, further comprising a timing controller including a memory and a compensator,
wherein the data driver includes a power switch, a sampling switch, an analog-to-digital converter, and a digital-to-analog converter that reflect the characteristics of the sub-pixel of the first pixel in the sub-pixel of the second pixel and compensate for the sub-pixel of the second pixel.

15. The display apparatus of claim 14, wherein the power switch operates to apply a reference voltage to each reference voltage line,
wherein the sampling switch controls connection between each reference voltage line and the analog-to-digital converter,
wherein the analog-to-digital converter outputs a voltage of each reference voltage line as a sensing value corresponding to a digital value,
wherein the compensator identifies characteristics of each sub-pixel based on the sensing value transmitted from the analog-to-digital converter and calculates a compensation value,
wherein the memory stores the calculated compensation value, and
wherein the digital-to-analog converter outputs image data changed based on the compensation value as an analog data voltage.

16. A method of driving a display apparatus comprising a display panel having pixels each including a plurality of sub-pixels, and a plurality of reference voltage lines that supply a reference voltage to each pixel, the method comprising:
a first process of performing, by a sensing switch, switching to selectively sense characteristics of a sub-pixel of one of a first pixel and a second pixel among the pixels; and
a second process of switching, by a sensing switch, a path along which the reference voltage is transmitted to one of a first reference voltage line and a second reference voltage line in order to separately drive the first reference voltage line and the second reference voltage line among the plurality of reference voltage lines.

17. The method of claim 16, wherein the first process comprises a process of switching a sensing switch to ON, so that the reference voltage is transmitted to the first reference voltage line and the second reference voltage line when the characteristics of the sub-pixel of the first pixel are defective.

18. The method of claim 17, wherein the second process comprises:
a process of reflecting the characteristics of the sub-pixel of the second pixel in a compensation value of the sub-pixel of the first pixel while the sensing switch maintains an ON state; and
a process of switching the driving switch from ON to OFF and separately driving the first reference voltage line and the second reference voltage line when the sensing switch is switched from OFF to ON.
